(19) United States
(12) Patent Application Publication
(10) Pub. No.: US 2026/0206335 A1
(43) Pub. Date: Jul. 16, 2026

(54) SEMICONDUCTOR LIGHT-RECEIVING ELEMENT

(71) Applicant: HAMAMATSU PHOTONICS K.K., Hamamatsu-shi, Shizuoka (JP)

(72) Inventors: Keiki TAGUCHI, Hamamatsu-shi, Shizuoka (JP); Kenji MAKINO, Hamamatsu-shi, Shizuoka (JP); Yoshiaki OHSHIGE, Hamamatsu-shi, Shizuoka (JP); Hajime ISHIHARA, Hamamatsu-shi, Shizuoka (JP)

(73) Assignee: HAMAMATSU PHOTONICS K.K., Hamamatsu-shi, Shizuoka (JP)

(21) Appl. No.: 18/866,150

(22) PCT Filed: Feb. 15, 2023
(86) PCT No.: PCT/JP2023/005274

§ 371 Date: Nov. 15, 2024

(30) Foreign Application Priority Data
Jun. 3, 2022 (JP) 2022-091023

(51) Int. Cl. H10F 30/223; H10F 77/124

(52) U.S. Cl. CPC H10F 30/223; H10F 77/1248

(57) ABSTRACT

Provided is a semiconductor light-receiving element including a substrate, and a semiconductor laminated portion formed on the substrate and including a back surface on the substrate side, a front surface on an opposite side from the substrate, and a side surface extending from the back surface toward the front surface, wherein the semiconductor laminated portion includes a light absorbing layer of a first conductivity type containing InₓGa₁₋ₓAs, a buffer layer of the first conductivity type provided between the substrate and the light absorbing layer, and a first semiconductor layer of a second conductivity type different from the first conductivity type located on an opposite side from the substrate with respect to the light absorbing layer and bonded to the light absorbing layer, an In composition x in the light absorbing layer is 0.55 or more, a thickness of the light absorbing layer is 1.8 μm or less.

### TECHNICAL FIELD

The present disclosure relates to a semiconductor light-receiving element.

### BACKGROUND ART

Patent Literature 1 describes an optical waveguide type light-receiving element. This optical waveguide type light-receiving element includes a first semiconductor layer having a first conductivity type, an optical waveguide structure provided on a first region of the first semiconductor layer, and a waveguide type photodiode structure provided on a second region adjacent to the first region of the first semiconductor layer. The optical waveguide structure includes an optical waveguide core layer provided on the first semiconductor layer, and a cladding layer provided on the optical waveguide core layer. The waveguide type photodiode structure includes a light absorbing layer which is provided on the first semiconductor layer, is optically coupled to the optical waveguide core layer, and has an absorption edge where a wavelength is 1612 nm or more, and a second semiconductor layer having a second conductivity type provided on the light absorbing layer. A length of the light absorbing layer in an optical waveguide direction is 12 μm or more.

### CITATION LIST

### Patent Literature

Patent Literature 1: Japanese Unexamined Patent Publication No. 2009-117499

### SUMMARY OF INVENTION

### Technical Problem

Incidentally, in the above technical field, there is a demand for even faster operating speed. To this end, it is conceivable to shorten moving distances of electrons by thinning the light absorbing layer. However, thinning the light absorbing layer results in a decrease in sensitivity. In response thereto, in a photodiode described in Patent Literature 1, light is made incident on the light absorbing layer from a direction intersecting a thickness direction of the light absorbing layer, thereby increasing an effective absorbing layer thickness (the light absorbing layer has a length of 12 μm in the optical waveguide direction). This is considered to achieve an increase in speed by suppressing a decrease in sensitivity caused by thinning the light absorbing layer. In this way, in the above-described technical field, there is a demand for an increase in speed.

An object of the disclosure is to provide a semiconductor light-receiving element capable of increasing speed.

### Solution to Problem

A semiconductor light-receiving element according to the disclosure is [1] “a semiconductor light-receiving element for receiving incidence of light in a wavelength band of at least one of a 1.3 μm band, a 1.55 μm band, and a 1.6 μm band and generating an electrical signal in response to incident light, the semiconductor light-receiving element including a substrate, a semiconductor laminated portion formed on the substrate and including a back surface on the substrate side, a front surface on an opposite side from the substrate, and a side surface extending from the back surface toward the front surface, and a first electrode and a second electrode electrically connected to the semiconductor laminated portion, wherein the semiconductor laminated portion includes a light absorbing layer of a first conductivity type containing InₓGa₁₋ₓAs, a buffer layer of the first conductivity type provided between the substrate and the light absorbing layer, and a first semiconductor layer of a second conductivity type different from the first conductivity type located on an opposite side from the substrate with respect to the light absorbing layer and bonded to the light absorbing layer, the first electrode is connected to a first part of the first conductivity type of the semiconductor laminated portion located on the substrate side with respect to the light absorbing layer, the second electrode is connected to a second part of the second conductivity type of the semiconductor laminated portion located on the opposite side from the substrate with respect to the light absorbing layer, an In composition x in the light absorbing layer is 0.55 or more, a thickness of the light absorbing layer is 1.8 μm or less, the semiconductor light-receiving element is of a side incidence type in which incidence of the light is received from the side surface, and a width of the light absorbing layer along an incident direction of the light with respect to the side surface is 10 μm or less”.

The semiconductor light-receiving element of [1] is intended for light in wavelength bands for optical communication, such as a 1.3 μm band (O-band (original band)), a 1.55 μm band (C-band (conventional band)), and a 1.6 μm band (L-band (long wavelength band)). In this semiconductor light-receiving element, the light absorbing layer provided on the substrate contains InₓGa₁₋ₓAs. Further, the In composition x of the light absorbing layer is 0.55 or more (and less than 1). In this way, when the In composition x of InₓGa₁₋ₓAs in the light absorbing layer is set to 0.55 or more, for example, an absorption coefficient is improved (the absorption coefficient is improved by about two times by setting the composition x to 0.62 in the 1.55 μm band) when compared to the case where the In composition x is 0.53. Therefore, even when the thickness of the light absorbing layer is reduced to approximately 1.8 μm or less, a decrease in sensitivity can be avoided. Thus, speed can be increased. Furthermore, for a similar reason, the width of the light absorbing layer in the incident direction of light can be set to 10 μm or less, and speed can be further increased by reducing the capacitance of the light absorbing layer.

The semiconductor light-receiving element according to the disclosure may be [2] “the semiconductor light-receiving element according to [1], wherein the buffer layer includes a strain relief layer having a lattice constant between a lattice constant of the substrate and a lattice constant of the light absorbing layer”. In this case, crystallinity of the semiconductor laminated portion is improved, and an increase in dark current is suppressed.

The semiconductor light-receiving element according to the disclosure may be [3] “the semiconductor light-receiving element according to [2], wherein the buffer layer includes a plurality of strain relief layers disposed so that the lattice constant approaches the lattice constant of the light absorbing layer stepwise from the substrate toward the light absorbing layer”. Alternatively, the semiconductor light-receiving element according to the disclosure may be [4] “the semiconductor light-receiving element according to [2], wherein the buffer layer includes the strain relief layer whose lattice constant continuously changes from the substrate toward the light absorbing layers so as to approach the lattice constant of the light absorbing layer”. In these cases, crystallinity of the semiconductor laminated portion is reliably improved, and an increase in dark current is suppressed.

The semiconductor light-receiving element according to the disclosure may be [5] “the semiconductor light-receiving element according to any one of [1] to [4], wherein the semiconductor laminated portion includes a cap layer of the second conductivity type provided on the light absorbing layer on the opposite side from the substrate with respect to the light absorbing layer and containing InAsP or InGaAsP, and a contact layer of the second conductivity type provided on the cap layer on the opposite side from the substrate with respect to the light absorbing layer and containing InGaAs, the first semiconductor layer includes the contact layer and the cap layer, and the second part to which the second electrode is connected is a front surface of the contact layer”. In this case, it is possible to reduce the contact resistance of the second electrode, and to reduce series resistance. In this way, it is possible to suppress deterioration of responsiveness. Furthermore, by using a material having a refractive index lower than the refractive index of the light absorbing layer for the cap layer, it becomes possible to suitably confine light in the light absorbing layer.

The semiconductor light-receiving element according to the disclosure may be [6] “the semiconductor light-receiving element according to any one of [1] to [5], wherein the semiconductor laminated portion includes a second semiconductor layer of the first conductivity type disposed between the optical waveguide layer and the light absorbing layer, and a capacitance reducing layer of the first conductivity type having an impurity concentration lower than an impurity concentration of the second semiconductor layer and disposed between the second semiconductor layer and the light absorbing layer”. By providing the capacitance reducing layer having a relatively low impurity concentration in this way, the capacitance reducing layer is depleted when a bias is applied, and thus speed is further increased due to a decrease in capacitance.

The semiconductor light-receiving element according to the disclosure may be [7] “the semiconductor light-receiving element according to [5], wherein the semiconductor laminated portion includes a third semiconductor layer provided between the light absorbing layer and the cap layer and having a band gap between a band gap of the light absorbing layer and a band gap of the cap layer”. In this case, by providing a layer having a band gap between that of the light absorbing layer and that of the cap layer between the layers, a barrier between the respective layers can be reduced, and response degradation can be suppressed.

The semiconductor light-receiving element according to the disclosure may be [8] “the semiconductor light-receiving element according to any one of [1] to [7], wherein at least one layer of the buffer layer is semi-insulated by being doped with Fe”. In this case, it is possible to reduce the capacitance.

The semiconductor light-receiving element according to the disclosure may be [9] “the semiconductor light-receiving element according to [6], wherein the capacitance reducing layer has an impurity concentration higher than an impurity concentration of the light absorbing layer, has a band gap larger than a band gap of the light absorbing layer, and is provided between the light absorbing layer and the optical waveguide layer”. In this case, as described above, the capacitance reducing layer is a layer that has a relatively low impurity concentration and contributes to reducing capacitance. However, simply lowering the impurity concentration of the capacitance reducing layer may increase the barrier between the layers, which may lead to deterioration of response. On the other hand, when the impurity concentration of the capacitance reducing layer is increased, the depletion layer does not expand, making it difficult to sufficiently reduce capacitance. Therefore, as described above, in order to decrease the impurity concentration of the capacitance reducing layer, if the capacitance reducing layer has a larger band gap than that of the light absorbing layer, light absorption in the capacitance reducing layer and generation of carriers in the capacitance reducing layer due to the light absorption are suppressed, and deterioration of response is suppressed. In addition, since the capacitance reducing layer has a larger band gap than that of the light absorbing layer, while the capacitance reducing layer has a higher impurity concentration than that of the light absorbing layer, the barrier in the capacitance reducing layer is reduced.

The semiconductor light-receiving element according to the disclosure may be [10] “the semiconductor light-receiving element according to [6] or [9], wherein a thickness of the capacitance reducing layer is 0.3 μm or more and 3.0 μm or less, and an impurity concentration of the capacitance reducing layer is 2.0×10¹⁴ cm⁻³ or more and 3.0×10¹⁶ cm⁻³ or less”. In this case, by setting an upper limit of the impurity concentration of the capacitance reducing layer as described above, the capacitance reducing layer can be suitably depleted when a bias is applied. In addition, by setting the thickness of the capacitance reducing layer in the above range, it is possible to suppress a decrease in response speed and an increase in series resistance of the semiconductor light-receiving element.

The semiconductor light-receiving element according to the disclosure may be [11] “the semiconductor light-receiving element according to any one of [1] to [10], wherein an In composition x in the light absorbing layer is 0.57 or more, and a thickness of the light absorbing layer is 1.2 μm or less”. Further, the semiconductor light-receiving element according to the disclosure may be [12] “the semiconductor light-receiving element according to [11], wherein the In composition x in the light absorbing layer is 0.59 or more, and the thickness of the light absorbing layer is 0.7 μm or less”. In these cases, by further thinning the light absorbing layer, speed may be increased.

The semiconductor light-receiving element according to the disclosure may be [13] “the semiconductor light-receiving element according to any one of [1] to [12], wherein the substrate includes a semi-insulating semiconductor”. In this case, by providing a pad of the first electrode on the substrate, pad capacitance can be reduced, enabling an increase in speed.

The semiconductor light-receiving element according to the disclosure may be [14] “the semiconductor light-receiving element according to any one of [1] to [13], wherein the substrate includes an insulator or a semi-insulating semiconductor, and the semiconductor laminated portion is bonded to the substrate”. In this case, by manufacturing the semiconductor light-receiving element by separately constructing and directly bonding the substrate and the semiconductor laminated portion, it is possible to increase a diameter and reduce costs by creating optical components using inexpensive materials.

The semiconductor light-receiving element according to the disclosure may be [15] “a semiconductor light-receiving element for receiving incidence of light in a wavelength band of at least one of a 1.3 μm band, a 1.55 μm band, and a 1.6 μm band and generating an electrical signal in response to incident light, the semiconductor light-receiving element including a substrate, a semiconductor laminated portion formed on the substrate and including a back surface on the substrate side, a front surface on an opposite side from the substrate, and a side surface extending from the back surface toward the front surface, and a first electrode and a second electrode electrically connected to the semiconductor laminated portion, wherein the semiconductor laminated portion includes a light absorbing layer of a second conductivity type containing InₓGa₁₋ₓAs, a buffer layer of a first conductivity type different from the second conductivity type provided between the substrate and the light absorbing layer, and a fourth semiconductor layer of the second conductivity type located on an opposite side from the substrate with respect to the light absorbing layer and bonded to the light absorbing layer, the first electrode is connected to a first part of the first conductivity type of the semiconductor laminated portion located on the substrate side with respect to the light absorbing layer, the second electrode is connected to a second part of the second conductivity type of the semiconductor laminated portion located on the opposite side from the substrate with respect to the light absorbing layer, an In composition x in the light absorbing layer is 0.55 or more, a thickness of the light absorbing layer is 1.8 μm or less, the semiconductor light-receiving element is of a side incidence type in which incidence of the light is received from the side surface, and a width of the light absorbing layer along an incident direction of the light with respect to the side surface is 10 μm or less”.

The semiconductor light-receiving element of [15] is intended for light in wavelength bands for optical communication, such as a 1.3 μm band (O-band (original band)), a 1.55 μm band (C-band (conventional band)), and a 1.6 μm band (L-band (long wavelength band)). In this semiconductor light-receiving element, the light absorbing layer provided on the substrate contains InₓGa₁₋ₓAs. Further, the In composition x of the light absorbing layer is 0.55 or more (and less than 1). In this way, when the In composition x of InₓGa₁₋ₓAs in the light absorbing layer is set to 0.55 or more, for example, an absorption coefficient is improved (the absorption coefficient is improved by about two times by setting the composition x to 0.62 in the 1.55 μm band) when compared to the case where the In composition x is 0.53. Therefore, even when the thickness of the light absorbing layer is reduced to approximately 1.8 μm or less, a decrease in sensitivity can be avoided. Furthermore, for a similar reason, the width of the light absorbing layer in the incident direction of light can be set to 10 μm or less, and speed can be further increased by reducing the capacitance of the light absorbing layer.

The semiconductor light-receiving element according to the disclosure may be [16] “the semiconductor light-receiving element according to [15], wherein the buffer layer includes a strain relief layer having a lattice constant between a lattice constant of the substrate and a lattice constant of the light absorbing layer”. In this case, crystallinity of the semiconductor laminated portion is improved, and an increase in dark current is suppressed.

The semiconductor light-receiving element according to the disclosure may be [17] “the semiconductor light-receiving element according to [16], wherein the buffer layer includes a plurality of strain relief layers disposed so that the lattice constant approaches the lattice constant of the light absorbing layer stepwise from the substrate toward the light absorbing layer”. Alternatively, the semiconductor light-receiving element according to the disclosure may be [18] “the semiconductor light-receiving element according to [16], wherein the buffer layer includes the strain relief layer whose lattice constant continuously changes from the substrate toward the light absorbing layers so as to approach the lattice constant of the light absorbing layer”. In these cases, crystallinity of the semiconductor laminated portion is reliably improved, and an increase in dark current is suppressed.

The semiconductor light-receiving element according to the disclosure may be [19] “the semiconductor light-receiving element according to any one of [15] to [18], wherein the semiconductor laminated portion includes a diffusion blocking layer of the second conductivity type provided on the light absorbing layer on the opposite side from the substrate with respect to the light absorbing layer and containing InAsP or InGaAsP, and a contact layer of the second conductivity type provided on the diffusion blocking layer on the opposite side from the substrate with respect to the light absorbing layer and containing InGaAs, the fourth semiconductor layer includes the contact layer and the diffusion blocking layer, and the second part to which the second electrode is connected is a front surface of the contact layer”. In this case, it is possible to reduce the contact resistance of the second electrode, and to reduce series resistance. In this way, it is possible to suppress deterioration of responsiveness. Furthermore, by using a material having a refractive index lower than the refractive index of the light absorbing layer for the diffusion blocking layer, it becomes possible to suitably confine light in the light absorbing layer.

The semiconductor light-receiving element according to the disclosure may be [20] “the semiconductor light-receiving element according to any one of [15] to [19], wherein the semiconductor laminated portion includes an electron transit layer of the first conductivity type provided between the buffer layer and the light absorbing layer, and an impurity concentration of the electron transit layer is lower than an impurity concentration of the buffer layer”. By relatively lowering the impurity concentration of the electron transit layer in this way, the electron transit layer is depleted when a bias is applied, and thus speed is further increased due to a decrease in capacitance.

The semiconductor light-receiving element according to the disclosure may be [21] “the semiconductor light-receiving element according to [19], wherein the semiconductor laminated portion includes a sixth semiconductor layer provided between the light absorbing layer and the diffusion blocking layer and having a band gap between a band gap of the light absorbing layer and a band gap of the diffusion blocking layer”. In this case, by providing a layer having a band gap between that of the light absorbing layer and that of the cap layer between the layers, a barrier between the respective layers can be reduced, and response degradation can be suppressed.

The semiconductor light-receiving element according to the disclosure may be [22] “the semiconductor light-receiving element according to any one of [15] to [21], wherein at least one layer of the buffer layer is semi-insulated by being doped with Fe”. In this case, it is possible to reduce the capacitance.

The semiconductor light-receiving element according to the disclosure may be [23] “the semiconductor light-receiving element according to [20], wherein the electron transit layer has an impurity concentration lower than an impurity concentration of the light absorbing layer, has a band gap larger than a band gap of the light absorbing layer, and is provided between the light absorbing layer and the optical waveguide layer”. In this case, the capacitance can be reduced by relatively lowering the impurity concentration of the electron transit layer. Furthermore, by lowering the impurity concentration of the electron transit layer, it is possible to facilitate depletion and reduce a barrier with respect to the light absorbing layer.

The semiconductor light-receiving element according to the disclosure may be [24] “the semiconductor light-receiving element according to [20] or [23], wherein a thickness of the electron transit layer is 0.3 μm or more and 3.0 μm or less, and the impurity concentration of the electron transit layer is 2.0×10¹⁴ cm⁻³ or more and 3.0×10¹⁶ cm⁻³ or less”. In this case, by setting an upper limit of the impurity concentration of the electron transit layer as described above, the electron transit layer can be suitably depleted when a bias is applied. In addition, by setting the thickness of the electron transit layer in the above range, it is possible to suppress a decrease in response speed and an increase in series resistance of the semiconductor light-receiving element.

The semiconductor light-receiving element according to the disclosure may be [25] “the semiconductor light-receiving element according to any one of [15] to [24], wherein the In composition x in the light absorbing layer is 0.57 or more, and the thickness of the light absorbing layer is 0.3 μm or less”. Further, the semiconductor light-receiving element according to the disclosure may be [26] “the semiconductor light-receiving element according to any one of [15] to , wherein the In composition x in the light absorbing layer is 0.59 or more, and the thickness of the light absorbing layer is 0.1 μm or less”. In these cases, by further thinning the light absorbing layer, speed may be increased.

The semiconductor light-receiving element according to the disclosure may be [27] “the semiconductor light-receiving element according to any one of [15] to [26], wherein the substrate includes a semi-insulating semiconductor”. In this case, by providing a pad of the first electrode on the substrate, pad capacitance can be reduced, enabling an increase in speed.

The semiconductor light-receiving element according to the disclosure may be [28] “the semiconductor light-receiving element according to any one of [15] to [27], wherein the substrate includes an insulator or a semi-insulating semiconductor, and the semiconductor laminated portion is bonded to the substrate”. In this case, by manufacturing the semiconductor light-receiving element by separately constructing and directly bonding the substrate and the semiconductor laminated portion, it is possible to increase a diameter and reduce costs by creating optical components using inexpensive materials.

The semiconductor light-receiving element according to the disclosure may be [29] “a semiconductor light-receiving element for receiving incidence of light in a wavelength band of at least one of a 1.3 μm band, a 1.55 μm band, and a 1.6 μm band and generating an electrical signal in response to incident light, the semiconductor light-receiving element including a substrate having a main surface including a first region, a second region, and a third region arranged in order along a first direction, a semiconductor laminated portion formed on the second region and including a back surface on the substrate side, a front surface on an opposite side from the substrate, and a side surface extending from the back surface toward the front surface, a first semiconductor portion of a first conductivity type formed on the first region, a second semiconductor portion of a second conductivity type different from the first conductivity type formed on the third region, a first electrode electrically connected to the first semiconductor portion, a second electrode electrically connected to the second semiconductor portion, and an optical waveguide formed on the second region, extending along the main surface and along a second direction intersecting the first direction toward the side surface, and coupled to the side surface, wherein the semiconductor laminated portion includes a light absorbing layer containing InₓGa₁₋ₓAs, an In composition x in the light absorbing layer is 0.55 or more, a thickness of the light absorbing layer is 1.8 μm or less, the semiconductor light-receiving element is of a side incidence type in which incidence of the light is received from the side surface via the optical waveguide, and a width of the light absorbing layer along an incident direction of the light with respect to the side surface is 10 μm or less”.

The semiconductor light-receiving element of [29] is intended for light in wavelength bands for optical communication, such as a 1.3 μm band (O-band (original band)), a 1.55 μm band (C-band (conventional band)), and a 1.6 μm band (L-band (long wavelength band)). In this semiconductor light-receiving element, the light absorbing layer provided on the substrate contains InₓGa₁₋ₓAs. Further, the In composition x of the light absorbing layer is 0.55 or more (and less than 1). In this way, when the In composition x of InₓGa₁₋ₓAs in the light absorbing layer is set to 0.55 or more, for example, an absorption coefficient is improved (the absorption coefficient is improved by about two times by setting the composition x to 0.62 in the 1.55 μm band) when compared to the case where the In composition x is 0.53. Therefore, even when the thickness of the light absorbing layer is reduced to approximately 1.8 μm or less, a decrease in sensitivity can be avoided. Furthermore, for a similar reason, the width of the light absorbing layer in the incident direction of light can be set to 10 μm or less, and speed can be further increased by reducing the capacitance of the light absorbing layer.

### Advantageous Effects of Invention

According to the disclosure, it is possible to provide a semiconductor light-receiving element capable of increasing speed.

### BRIEF DESCRIPTION OF DRAWINGS

FIG. 1 is a schematic plan view illustrating a semiconductor light-receiving element according to a first embodiment.

FIG. 2 is a schematic cross-sectional view taken along line II-II of FIG. 1.

FIG. 3 is a schematic cross-sectional view taken along line III-III of FIG. 1.

FIG. 4 is a graph describing a relationship between a composition and an absorption coefficient of a light absorbing layer.

FIG. 5 is a schematic cross-sectional view of a semiconductor light-receiving element according to a second embodiment.

FIG. 6 is a schematic cross-sectional view of a semiconductor light-receiving element according to a third embodiment.

FIG. 7 is a schematic cross-sectional view of a semiconductor light-receiving element according to a fourth embodiment.

FIG. 8 is a schematic cross-sectional view of a semiconductor light-receiving element according to a fifth embodiment.

FIG. 9 is a schematic plan view of a semiconductor light-receiving element according to a sixth embodiment.

FIG. 10 is a schematic cross-sectional view taken along line X-X of FIG. 9.

FIG. 11 is a schematic cross-sectional view taken along line XI-XI of FIG. 9.

FIG. 12 is a cross-sectional view illustrating a modified example of the semiconductor light-receiving element illustrated in FIG. 11.

FIG. 13 is a schematic cross-sectional view of a semiconductor light-receiving element according to a seventh embodiment.

FIG. 14 is a schematic cross-sectional view of the semiconductor light-receiving element according to the seventh embodiment.

### DESCRIPTION OF EMBODIMENTS

Hereinafter, embodiments will be described in detail with reference to the drawings. In each drawing, the same or corresponding elements are denoted by the same reference numerals, and duplicated descriptions may be omitted.

### First Embodiment

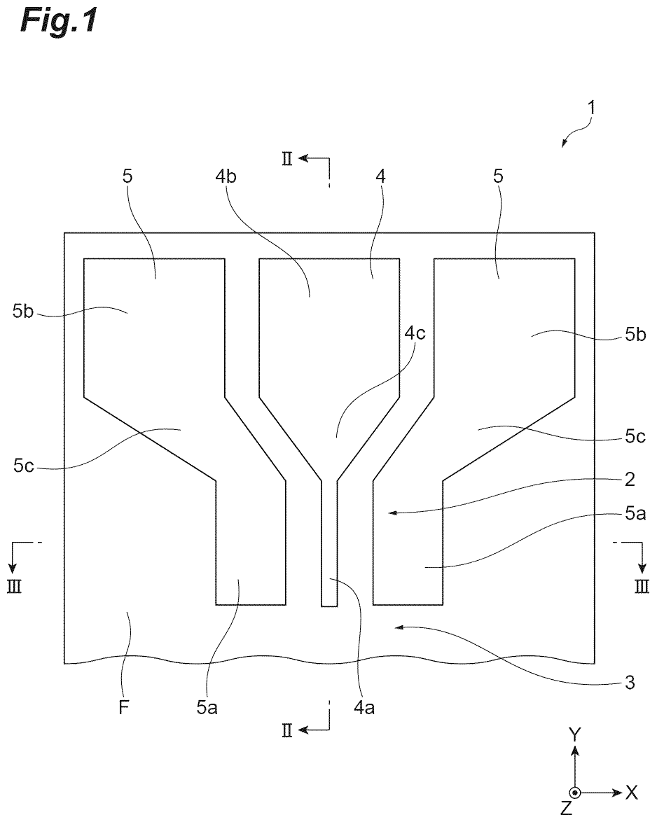

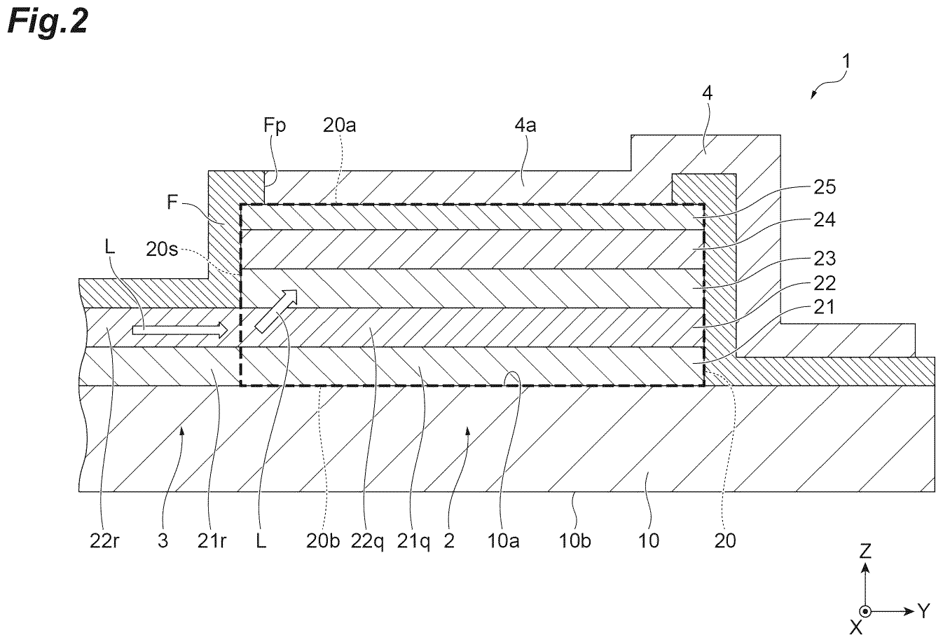

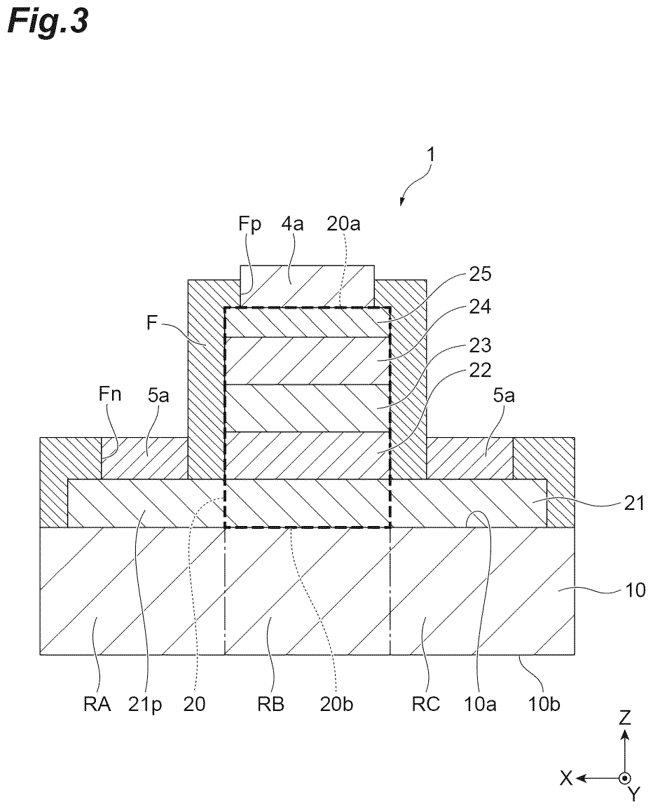

FIG. 1 is a schematic plan view illustrating a semiconductor light-receiving element according to a first embodiment. FIG. 2 is a schematic cross-sectional view taken along line II-II of FIG. 1. FIG. 3 is a schematic cross-sectional view taken along line III-III of FIG. 1. The semiconductor light-receiving element illustrated in FIGS. 1 to 3 is intended for light in wavelength bands for optical communication, such as a 1.3 μm band (O-band (original band)), a 1.55 μm band (C-band (conventional band)), and a 1.6 μm band (L-band (long wavelength band)). In other words, the semiconductor light-receiving element 1 receives light in at least one of the above-mentioned wavelength bands and generates an electrical signal in response to incident light. The 1.3 μm band is, for example, a wavelength range of 1.26 μm or more and 1.36 μm or less. The 1.55 μm band is, for example, a wavelength range of 1.53 μm or more and 1.565 um or less. The 1.6 μm band is, for example, a wavelength range of greater than 1.565 μm and 1.625 μm or less. Furthermore, light in a wavelength band for communication is light having a peak within a wavelength range of any of the wavelength bands (that is, a wavelength other than the peak may be outside the wavelength range of the wavelength bands).

The semiconductor light-receiving element 1 includes a substrate 10, a semiconductor laminated portion 20, an electrode 4 (second electrode), and a pair of electrodes 5 (first electrodes). The electrode 4 includes a joint portion 4a bonded to the semiconductor laminated portion 20, a pad portion 4b, and a connection portion 4c connecting the joint portion 4a and the pad portion 4b. The connection portion 4c is wider from the joint portion 4a toward the pad portion 4b. The electrodes 5 each includes a joint portion 5a bonded to the semiconductor laminated portion 20, a pad portion 5b, and a connection portion 5c connecting the joint portion 5a and the pad portion 5b. The connection portion 5c is wider from the joint portion 5a toward the pad portion 5b.

The substrate 10 includes a semi-insulating semiconductor. Here, the substrate 10 is, for example, a semi-insulating semiconductor substrate made of InP. The substrate 10 includes a front surface (main surface) 10a and a back surface 10b on the opposite side from the front surface 10a. Further, the substrate 10 includes a region RA, a region RB, and a region RC arranged in order along an X-axis direction (first direction) along the front surface 10a and the back surface 10b. The region RB is a region between the region RA and the region RC, and is a region in which the semiconductor laminated portion 20 is provided.

As described above, the semiconductor laminated portion 20 is formed on the region RB of the substrate 10, and is formed as a semiconductor mesa protruding from the front surface 10a. The semiconductor laminated portion 20 includes a back surface 20b on the substrate 10 side, a front surface 20a on the opposite side from the substrate 10, and a side surface 20s extending from the back surface 20b toward the front surface 20a. The side surface 20s connects the back surface 20b and the front surface 20a to each other. The semiconductor laminated portion 20 includes a buffer layer 21, a capacitance reducing layer 22, a light absorbing layer 23, a cap layer 24 (first semiconductor layer), and a contact layer 25 (first semiconductor layer), which are stacked in this order from the substrate 10 side. The front surface 20a is a front surface of the contact layer 25 on the opposite side from the light absorbing layer 23, and the back surface 20b is a front surface of the buffer layer 21 on the opposite side from the light absorbing layer 23 and is in contact with the front surface 10a of the substrate 10.

The buffer layer 21 has a first conductivity type (N-type here, N+-type as an example). The buffer layer 21 is provided across the region RA and the region RC with the region RB at a center. Here, the semiconductor laminated portion 20 contacts the front surface 10a of the substrate 10 at the buffer layer 21. The layers of the semiconductor laminated portion 20 other than the buffer layer 21 are provided on the region RB. That is, the buffer layer 21 has a part 21p protruding from the other layers of the semiconductor laminated portion 20 when viewed from a direction intersecting the front surface 10a, and is bonded to the electrode 5 (joint portion 5a) at the part 21p.

The buffer layer 21 includes a first buffer layer, a second buffer layer, and a third buffer layer, which are stacked in this order from the substrate 10 side. As an example, the first buffer layer is made of N⁺-InP, the second buffer layer is made of N⁺-InAs_{0.05}P, and the third buffer layer is made of N⁺-InAs_{0.10}P. The capacitance reducing layer 22 has the first conductivity type (N-type here, N⁻-type as an example) and is made of N⁻-InAs_{0.15}P, as an example.

In this way, the buffer layer 21 and the capacitance reducing layer 22 function as strain relief layers having a lattice constant between a lattice constant of the substrate 10 and a lattice constant of the light absorbing layer 23. In other words, the semiconductor laminated portion 20 includes a plurality of strain relief layers (step layers) provided so that the lattice constant approaches the lattice constant of the light absorbing layer 23 stepwise from the substrate 10 toward the light absorbing layer 23. A thickness of the buffer layer 21 is, for example, 0.5 μm or more and 5 μm or less.

In addition, the capacitance reducing layer 22 is disposed on the light absorbing layer 23 side of the buffer layer 21, and has an impurity concentration lower than the impurity concentration of the buffer layer 21. The light absorbing layer 23 has the first conductivity type (for example, N⁻-type). The light absorbing layer 23 contains InGaAs. Here, the light absorbing layer 23 is made of N⁻-InₓGa₁₋ₓAs. Further, an In composition x in the light absorbing layer 23 is 0.55 or more (and less than 1). As an example, the In composition x may be 0.57 or more, and is 0.59 or more here (as an example, 0.59).

Further, a thickness of the light absorbing layer 23 (a thickness along a stacking direction (Z-axis direction) of the semiconductor laminated portion 20) is 0.6 μm or more and 1.8 μm or less. As an example, the thickness of the light absorbing layer 23 may be 1.2 μm or less, and is 0.7 μm or less here (as an example, 0.7 μm). Note that the light absorbing layer 23 may be an absorbing layer made of a mixed crystal of InGaAs and Al, P, Sb, N, or other material, with a band gap in a range of 0.72 eV or less. A proportion of Al, P, Sb, and N (or other material) mixed into InGaAs can be set to, for example, 5% or less, or 10% or less.

Here, the capacitance reducing layer 22 has an impurity concentration higher than the impurity concentration of the light absorbing layer 23. As an example, the impurity concentration of the capacitance reducing layer 22 is about 2.0×10¹⁴ cm⁻³ or more and 3.0×10¹⁶ cm⁻³, and the impurity concentration of the light absorbing layer 23 is about 1.0×10¹⁴ cm⁻³ or more and 1.0×10¹⁶ cm⁻³ or less. In addition, the capacitance reducing layer 22 has a band gap larger than the band gap of the light absorbing layer 23. When the band gap of the light absorbing layer 23 is 0.72 eV or less as described above, the band gap of the capacitance reducing layer 22 may be in a range of greater than 0.72 eV and 1.35 eV or less.

In this way, the semiconductor laminated portion 20 has the capacitance reducing layer 22 provided between the buffer layer 21 and the light absorbing layer 23. Requirements for the capacitance reducing layer 22 are that the impurity concentration is higher than that of the light absorbing layer 23 as described above, and the capacitance reducing layer 22 is depleted when a bias is applied. A reason therefor is that, as described above, the capacitance reducing layer 22 has a larger band gap than the light absorbing layer 23, and thus when the impurity concentration is low, there is concern that a barrier may be created in a conduction band, which may hinder movement of carriers having a large barrier to fail suitable extraction.

In addition, since the capacitance reducing layer 22 needs to be depleted when a bias is applied, an upper limit of the impurity concentration can be set to about 3.0×10¹⁶ cm⁻³ as described above. Furthermore, the capacitance reducing layer 22 desirably has a composition that does not absorb incident light (that is, the band gap is desirably wider than that of the light absorbing layer 23). When the capacitance reducing layer 22 absorbs incident light, carriers are generated in the capacitance reducing layer 22. The carriers are extracted as signals from the capacitance reducing layer 22 via the light absorbing layer 23, and therefore become slow carriers, which may degrade response characteristics.

In other words, by setting a relationship between the buffer layer 21, the capacitance reducing layer 22, and the light absorbing layer 23 as described above, it is possible to make the capacitance reducing layer 22 function as a layer that can reduce capacitance without lowering the carrier response. Since the capacitance reducing layer 22 is effective when provided, the thickness thereof is not particularly limited, but can be set to 0.3 μm or more and 3 μm or less as an example.

Note that, by providing a P-type semiconductor layer between the light absorbing layer 23 and the cap layer 24 described below, the semiconductor layer can be used as a capacitance reducing layer. However, since an N-type semiconductor layer is easier to manufacture than a P-type semiconductor layer, and electrons have greater mobility when compared to a carrier speed in a Player, it is considered more effective to form an N⁻-type capacitance reducing layer 22 directly below the light absorbing layer 23 (to be in contact with the light absorbing layer 23 between the light absorbing layer 23 and the buffer layer 21).

Furthermore, in the semiconductor light-receiving element 1, the light absorbing layer 23 is a single layer. That the light absorbing layer 23 is a single layer means that the light absorbing layer 23 does not have a stacked structure formed by stacking two or more layers having different compositions or characteristics. More specifically, that the light absorbing layer 23 is a single layer means that, for example, the light absorbing layer 23 does not have a superlattice structure formed by repeatedly stacking a plurality of layers having different compositions.

The cap layer 24 has a second conductivity type (P-type here, P⁺-type as an example) different from the first conductivity type. The cap layer 24 includes InAsP or InGaAsP. Here, the cap layer 24 includes InAsP. As an example, the cap layer 24 is made of P⁺-InAs_{0.15}P. A thickness of the cap layer 24 is, for example, 0.05 μm or more and 2.5 μm or less.

The contact layer 25 has the second conductivity type (P-type here, P⁺-type as an example). The contact layer 25 contains InGaAs. As an example, the contact layer 25 is made of P⁺-InGaAs. A thickness of the contact layer 25 is, for example, 0.025 μm or more and 0.2 μm or less. In this way, the semiconductor laminated portion 20 includes a first semiconductor layer of the second conductivity type located on the opposite side from the substrate 10 with respect to the light absorbing layer 23 and bonded to the light absorbing layer 23. The first semiconductor layer includes the cap layer 24 and the contact layer 25.

Note that, in the above example, N⁺-type means that N-type impurity concentration is about 1×10¹⁷ cm⁻³ or more. N⁻-type means that the N-type impurity concentration is about 3.0×1016 cm⁻³ or less, which is relatively low compared to N⁺-type. In addition, P⁺-type means that P-type impurity concentration is about 1×10¹⁷ cm⁻³ or more.

The semiconductor light-receiving element 1 has a protective film (passivation film) F. The protective film F is, for example, an insulating film. A part of the front surface 20a (top surface) of the semiconductor laminated portion 20 and the side surface 20s of the semiconductor laminated portion 20 extending from the periphery of the front surface 20a toward the substrate 10 side are covered by the protective film F. On the other hand, the remainder of the front surface 20a of the semiconductor laminated portion 20, here, a part of the front surface of the contact layer 25, is exposed from an opening Fp in the protective film F.

Further, the joint portion 4a of the electrode 4 is formed in the part of the front surface 20a exposed from the protective film F, and a bond is formed between the electrode 4 and the semiconductor laminated portion 20 (contact layer 25). That is, the electrode 4 is connected to a second part of the second conductivity type (here, the front surface of the contact layer 25) located on the opposite side from the substrate 10 with respect to the light absorbing layer 23 in the semiconductor laminated portion 20. Meanwhile, a part of the front surface of the part 21p of the buffer layer 21 is exposed from the opening Fn of the protective film F, the joint portion 5a of the electrode 5 is formed in this exposed part, and a bond is formed between the electrode 5 and the semiconductor laminated portion 20 (buffer layer 21). In other words, the electrode 5 is connected to a first part of the first conductivity type (the front surface of the buffer layer 21) located on the substrate 10 side with respect to the light absorbing layer 23 in the semiconductor laminated portion 20.

Here, the semiconductor light-receiving element 1 has a light-receiving portion 2 including the above-mentioned semiconductor laminated portion 20, and a waveguide portion 3 that propagates light toward the light-receiving portion 2. The waveguide portion 3 includes the buffer layer 21 and the capacitance reducing layer 22 provided on the front surface 10a of the substrate 10. More specifically, the buffer layer 21 and the capacitance reducing layer 22 are each provided to extend outside the light-receiving portion 2 (semiconductor laminated portion 20) along a Y-axis direction (a second direction intersecting the first direction) along the front surface 10a and the back surface 10b of the substrate 10, and the waveguide portion 3 is formed by the parts of the buffer layer 21 and the capacitance reducing layer 22 that extend to the outside of the light-receiving portion 2.

In other words, the buffer layer 21 includes a part 21q included in the semiconductor laminated portion 20 and a part 21r extending from the side surface 20s of the semiconductor laminated portion 20 to the outside of the semiconductor laminated portion 20, and the capacitance reducing layer 22 includes a part 22q included in the semiconductor laminated portion 20 and a part 22r extending from the side surface 20s of the semiconductor laminated portion 20 to the outside of the semiconductor laminated portion 20. Further, the waveguide portion 3 is formed by the parts 21r and 22r. A front surface of the part 22r on the opposite side from the substrate 10 is covered by the protective film F.

The semiconductor light-receiving element 1 is of a side incidence type in which light L guided by the buffer layer 21 and the capacitance reducing layer 22 in the waveguide portion 3 is received from the side surface 20s of the semiconductor laminated portion 20. Therefore, in the semiconductor light-receiving element 1, the buffer layer 21 and the capacitance reducing layer 22 are also optical waveguide layers of the first conductivity type provided between the substrate 10 and the light absorbing layer 23. The buffer layer 21, the capacitance reducing layer 22, and the light absorbing layer 23 have refractive indexes increasing in this order.

Therefore, the light L propagating through the waveguide portion 3 is incident on the semiconductor laminated portion 20 from the side surface 20s of the semiconductor laminated portion 20 while being distributed mainly in the capacitance reducing layer 22, transitions from the buffer layer 21 and the capacitance reducing layer 22 side to the light absorbing layer 23, and is absorbed in the light absorbing layer 23. In other words, the semiconductor light-receiving element 1 is of the side incidence type. The light L incident from the side surface 20s reaches the light absorbing layer 23 via the optical waveguide layers. A width of the light absorbing layer 23 along an incident direction of the light L on the side surface 20s (Y-axis direction) is, for example, 2 μm or more and 10 μm or less. Note that, by making a refractive index of the light absorbing layer 23 lower than a refractive index of the cap layer 24, it is possible to suitably confine the light L inside the light absorbing layer 23. In addition, a refractive index of the substrate 10 may be lower than the refractive index of the buffer layer 21, but may be higher than the refractive index of the buffer layer 21.

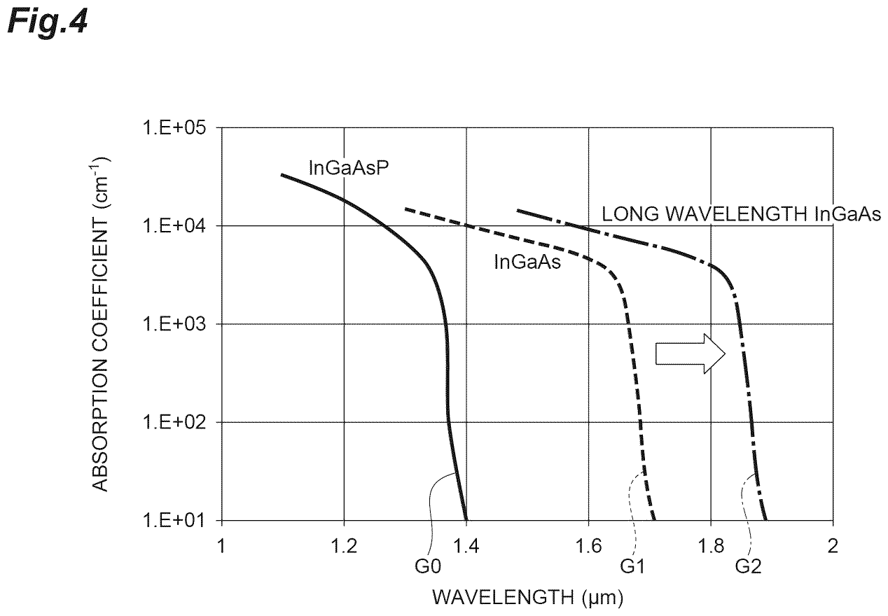

As described above, the semiconductor light-receiving element 1 is intended for light in wavelength bands used for optical communication, such as the 1.3 μm band, the 1.55 μm band, and the 1.6 μm band. In the semiconductor light-receiving element 1, the light absorbing layer 23 provided on the substrate 10 contains InₓGa₁₋ₓAs. Further, the In composition x in the light absorbing layer 23 is 0.55 or more (and less than 1). In this way, when the In composition x of InₓGa₁₋ₓAs in the light absorbing layer 23 is set to 0.55 or more (graph G2 of FIG. 4), for example, an absorption coefficient is improved (improved by about two times in the 1.55 μm band in an example of FIG. 4) when compared to the case where the In composition x indicated by graph G1 of FIG. 4 is 0.53. Note that graph GO of FIG. 4 indicates the case where a light absorbing layer made of InGaAsP is used.

Therefore, even when the thickness of the light absorbing layer 23 is reduced to approximately 1.8 μm or less, a decrease in sensitivity can be avoided. In other words, higher speeds are possible. Furthermore, even though the semiconductor light-receiving element 1 is of the side incidence type in which light is incident on the semiconductor laminated portion 20 from the side surface 20s of the semiconductor laminated portion 20, light incident from the side surface 20s reaches the light absorbing layer 23 via the optical waveguide layers (at least the capacitance reducing layer 22) on the substrate 10 side of the light absorbing layer 23. In other words, in the semiconductor light-receiving element 1, light is incident at least obliquely with respect to the Y-axis direction that intersects with the thickness of the light absorbing layer 23. In this way, a region in which light is absorbed in the light absorbing layer 23 is increased when compared to the case where light is directly incident in the Y-axis direction from an end surface of the light absorbing layer. As a result, degradation of characteristics such as frequency characteristics and linearity is suppressed without occurrence of a local increase in photocarrier density. Therefore, according to the semiconductor light-receiving element 1, it is possible to increase speed while suppressing degradation of characteristics. Furthermore, according to the semiconductor light-receiving element 1, it is possible to set the width of the light absorbing layer 23 to 10 μm or less in the incident direction of the light while avoiding a decrease in sensitivity, and it is possible to reduce the capacitance of the light absorbing layer 23 to further increase speed.

In addition, in the semiconductor light-receiving element 1, the semiconductor laminated portion 20 includes the buffer layer 21 of the first conductivity type provided between the substrate 10 and the light absorbing layer 23. Therefore, by increasing the impurity concentration of the buffer layer 21, it is possible to suitably use the buffer layer 21 for forming a contact with the electrode 5. Furthermore, by providing the buffer layer 21 below the light absorbing layer 23, degradation of response can be suppressed.

Furthermore, in the semiconductor light-receiving element 1, the buffer layer 21 includes the strain relief layer (first to third buffer layers) having the lattice constant between the lattice constant of the substrate 10 and the lattice constant of the light absorbing layer 23. For this reason, crystallinity of the semiconductor laminated portion 20 is improved, and an increase in dark current is suppressed.

Furthermore, in the semiconductor light-receiving element 1, the buffer layer 21 includes a plurality of strain relief layers (first to third buffer layers) provided so that the lattice constant approaches the lattice constant of the light absorbing layer 23 stepwise from the substrate 10 toward the light absorbing layer 23. For this reason, crystallinity of the semiconductor laminated portion is reliably improved, and an increase in dark current is suppressed.

Furthermore, in the semiconductor light-receiving element 1, the semiconductor laminated portion 20 includes the cap layer 24 of the second conductivity type (first semiconductor layer) which is provided on the light absorbing layer 23 on the opposite side from the substrate 10 with respect to the light absorbing layer 23 and contains InAsP, and the contact layer 25 of the second conductivity type (first semiconductor layer) which is provided on the cap layer 24 on the opposite side from the substrate 10 with respect to the light absorbing layer 23 and contains InGaAs. Further, a second part to which the electrode 4 is connected is the front surface of the contact layer 25. For this reason, it is possible to reduce the contact resistance of the electrode 4, and to reduce series resistance. In this way, it is possible to suppress deterioration of responsiveness. Furthermore, by using a material having a refractive index lower than the refractive index of the light absorbing layer 23 for the cap layer 24, it becomes possible to suitably confine light in the light absorbing layer 23.

Furthermore, in the semiconductor light-receiving element 1, the semiconductor laminated portion 20 includes the capacitance reducing layer 22 of the first conductivity type which is disposed between the substrate 10 (buffer layer 21) and the light absorbing layer 23 and has an impurity concentration lower than the impurity concentration of the buffer layer 21. By providing the capacitance reducing layer 22 having a relatively low impurity concentration in this way, the capacitance reducing layer 22 is depleted when a bias is applied, and thus speed is further increased due to a decrease in capacitance.

In addition, in the semiconductor light-receiving element 1, the capacitance reducing layer 22 has a higher impurity concentration than the impurity concentration of the light absorbing layer 23, has a larger band gap than the band gap of the light absorbing layer 23, and is provided between the light absorbing layer 23 and the buffer layer 21. As described above, the capacitance reducing layer 22 is a layer that has a relatively low impurity concentration and contributes to reducing capacitance. However, simply lowering the impurity concentration of the capacitance reducing layer 22 may increase the barrier between the layers, which may lead to deterioration of response. On the other hand, when the impurity concentration of the capacitance reducing layer 22 is increased, the depletion layer does not expand, making it difficult to sufficiently reduce capacitance.

Therefore, as described above, when the impurity concentration of the capacitance reducing layer 22 is decreased, if the capacitance reducing layer 22 has a larger band gap than that of the light absorbing layer 23, light absorption in the capacitance reducing layer 22 and generation of carriers in the capacitance reducing layer 22 due to the light absorption are suppressed, and deterioration of response is suppressed. In addition, since the capacitance reducing layer 22 has a larger band gap than that of the light absorbing layer 23, while the capacitance reducing layer 22 has a higher impurity concentration than that of the light absorbing layer 23, the barrier in the capacitance reducing layer 22 is reduced.

In addition, in the semiconductor light-receiving element 1, the thickness of the capacitance reducing layer 22 is 0.3 μm or more and 3.0 um or less, and the impurity concentration of the capacitance reducing layer 22 is 2.0×10¹⁴ cm⁻³ or more and 3.0×10¹⁶ cm⁻³ or less. Therefore, by setting an upper limit of the impurity concentration of the capacitance reducing layer 22 as described above, the capacitance reducing layer 22 can be suitably depleted when a bias is applied. In addition, by setting the thickness of the capacitance reducing layer 22 in the above range, it is possible to suppress a decrease in response speed and an increase in series resistance of the semiconductor light-receiving element 1.

In addition, in the semiconductor light-receiving element 1, the In composition x in the light absorbing layer 23 is 0.57 or more, and the thickness of the light absorbing layer 23 is 1.2 μm or less. In addition, in the semiconductor light-receiving element 1, the In composition x in the light absorbing layer 23 is 0.59 or more, and the thickness of the light absorbing layer 23 is 0.7 μm or less. Therefore, by further thinning the light absorbing layer 23, speed may be increased.

In addition, in the semiconductor light-receiving element 1, the substrate 10 includes the semi-insulating semiconductor. Therefore, by providing the pad portion 5b of the electrode 5 on the substrate 10, the pad capacitance can be reduced, enabling an increase in speed.

In the semiconductor light-receiving element 1, the buffer layer 21 is included in at least a part of the optical waveguide layer, but may include a layer semi-insulated by being doped with Fe. In this case, it is possible to reduce the capacitance.

Furthermore, in the semiconductor light-receiving element 1, the semiconductor laminated portion 20 may include a third semiconductor layer which is provided between the light absorbing layer 23 and the cap layer 24 and has a band gap between a band gap of the light absorbing layer 23 and a band gap of the cap layer 24. In this case, by providing a layer having a band gap between that of the light absorbing layer 23 and that of the cap layer 24 between the layers, a barrier between the respective layers can be reduced, and response degradation can be suppressed.

Listed below are examples of combinations of each wavelength band, the thickness of the light absorbing layer 23, and the In composition x in the light absorbing layer 23. Note that, for example, the following (5), etc. can be configured similarly not only for the C-band but also for the O-band and the L-band.

### (1) C-Band.

Sensitivity: 0.86 A/W or more.
Cutoff frequency: 20 GHz or more (for 28 GB, etc.).
Absorption layer thickness: 1.5 μm.
In composition x: x=0.55.

### (2) C-Band.

Sensitivity: 0.90 A/W or more.
Cutoff frequency: 20 GHz or more (for 28 GB high sensitivity product).
Absorption layer thickness: 1.5 μm.
In composition x: x=0.57.

### (3) C-Band.

Sensitivity: 0.80 A/W or more.
Cutoff frequency: 30 GHz or more (for 56 GB, etc.).
Absorption layer thickness: 1.2 μm.
In composition x: x=0.57.

### (4) C-Band.

Sensitivity 0.85 A/W or more.
Cutoff frequency: 30 GHz or more (for 56 GB high sensitivity product).
Absorption layer thickness: 1.2 μm.
In composition x: x=0.59.

### (5) C-Band.

Sensitivity 0.7 A/W or more.
Cutoff frequency: 45 GHz or more (for 96 GB, etc.).
Absorption layer thickness: 0.7 μm.
In composition x: x=0.59.

### (6) C-band.

Sensitivity 0.90 A/W or more.
Cutoff frequency: 16 GHz or more (for 25 GB, etc.).
Absorption layer thickness: 1.8 μm.
In composition x: x=0.55.

### (7) C-Band.

Sensitivity 0.93 A/W or more.
Cutoff frequency: 16 GHz or more (for 25 GB, etc.).
Absorption layer thickness: 1.8 μm.
In composition x: x=0.57.

### Second Embodiment

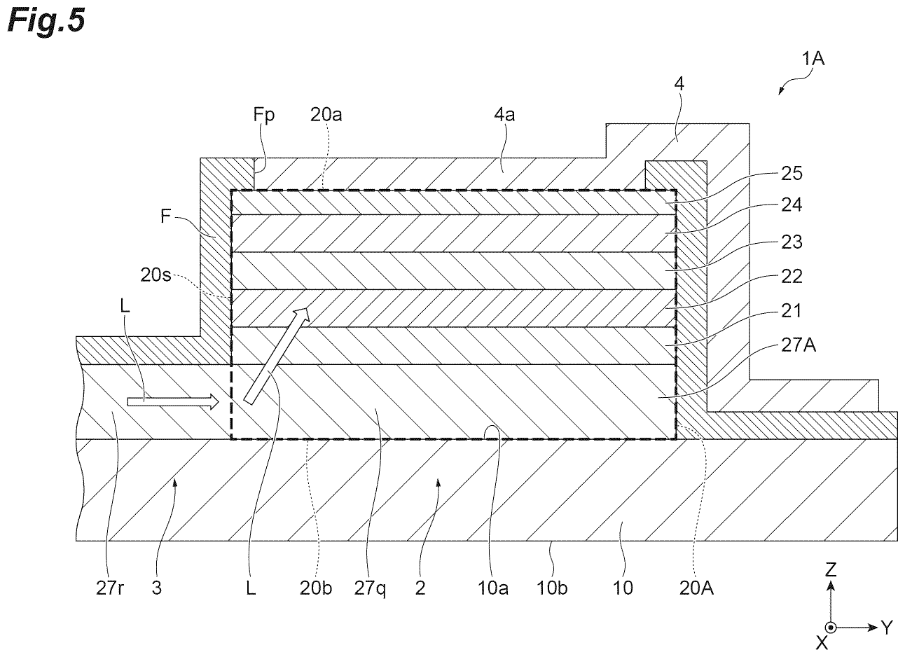

FIG. 5 is a schematic cross-sectional view of a semiconductor light-receiving element according to a second embodiment. As illustrated in FIG. 5, a semiconductor light-receiving element 1A is different from the semiconductor light-receiving element 1 according to the first embodiment in that a semiconductor laminated portion 20A is included instead of the semiconductor laminated portion 20. The semiconductor laminated portion 20A further includes an optical waveguide layer 27A in addition to the respective layers of the semiconductor laminated portion 20. The optical waveguide layer 27A is provided between the light absorbing layer 23 and the substrate 10, more specifically, between the buffer layer 21 and the substrate 10.

The optical waveguide layer 27A is in contact with the front surface 10a of the substrate 10. In the semiconductor light-receiving element 1A, the refractive index increases in the order of the optical waveguide layer 27A, the buffer layer 21, the capacitance reducing layer 22, and the light absorbing layer 23. The optical waveguide layer 27A includes, for example, InGaAsP. The optical waveguide layer 27A may be made of a material not including a dopant (for example, a non-doped material) to reduce optical loss. Alternatively, the optical waveguide layer 27A may be made of an insulating material for a similar reason. Note that the refractive index of the substrate 10 may be lower than that of the optical waveguide layer 27A, and may be higher than that of the optical waveguide layer 27A.

The optical waveguide layer 27A includes a part 27q included in the semiconductor laminated portion 20A and a part 27r that extends from the side surface 20s of the semiconductor laminated portion 20A to the outside of the semiconductor laminated portion 20A. A front surface of the part 27r on the opposite side from the substrate 10 is covered by the protective film F. In the semiconductor light-receiving element 1A, the waveguide portion 3 is formed by the part 27r. The semiconductor light-receiving element 1A is of the side incidence type in which the light L guided by the optical waveguide layer 27A (part 27r) in the waveguide portion 3 is received from the side surface 20s of the semiconductor laminated portion 20A. In the semiconductor light-receiving element 1A, the light L propagating through the waveguide portion 3 (optical waveguide layer 27A) is incident on the semiconductor laminated portion 20A from the side surface 20s of the semiconductor laminated portion 20A, transitions from the optical waveguide layer 27A side to the light absorbing layer 23, and is absorbed in the light absorbing layer 23. That is, the semiconductor light-receiving element 1A is of the side incidence type. The light L incident from the side surface 20s reaches the light absorbing layer 23 via the optical waveguide layer 27A (as well as the buffer layer 21 and the capacitance reducing layer 22).

Meanwhile, in the semiconductor light-receiving element 1A, the buffer layer 21 and the capacitance reducing layer 22 terminate at the side surface 20s (end surfaces of the buffer layer 21 and the capacitance reducing layer 22 are flush with the end surface of the light absorbing layer 23) and do not extend outside the side surface 20s. In the semiconductor light-receiving element 1A, the semiconductor laminated portion 20A includes the buffer layer 21 (second semiconductor layer) of the first conductivity type provided between the optical waveguide layer 27A and the light absorbing layer 23, and the capacitance reducing layer 22 of the first conductivity type which has an impurity concentration lower than the impurity concentration of the buffer layer 21 and is provided between the buffer layer 21 and the light absorbing layer 23. The capacitance reducing layer 22 has an impurity concentration higher than the impurity concentration of the light absorbing layer 23, has a band gap larger than the band gap of the light absorbing layer 23, and is provided between the light absorbing layer 23 and the optical waveguide layer 27A.

The above-described semiconductor light-receiving element 1A can also achieve similar effects to those of the semiconductor light-receiving element 1. In particular, in the semiconductor light-receiving element 1A, the optical waveguide layer 27A, which is responsible for propagating light to the light-receiving portion 2, and the buffer layer 21 are configured as separate layers. Therefore, it is possible to suitably use the buffer layer 21 for forming a contact with the electrode 5 by increasing the impurity concentration of the buffer layer 21 without causing optical loss due to an increase in the impurity concentration of the optical waveguide layer 27A (due to free electron absorption).

Further, in the semiconductor light-receiving element 1A, the semiconductor laminated portion 20A includes the buffer layer 21 (second semiconductor layer) of the first conductivity type provided between the optical waveguide layer 27A and the light absorbing layer 23, and the capacitance reducing layer 22 of the first conductivity type which has an impurity concentration lower than the impurity concentration of the buffer layer 21 and is provided between the buffer layer 21 and the light absorbing layer 23. By providing the capacitance reducing layer 22 having a relatively low impurity concentration in this way, the capacitance reducing layer 22 is depleted when a bias is applied, and thus speed is further increased due to a decrease in capacitance.

### Third Embodiment

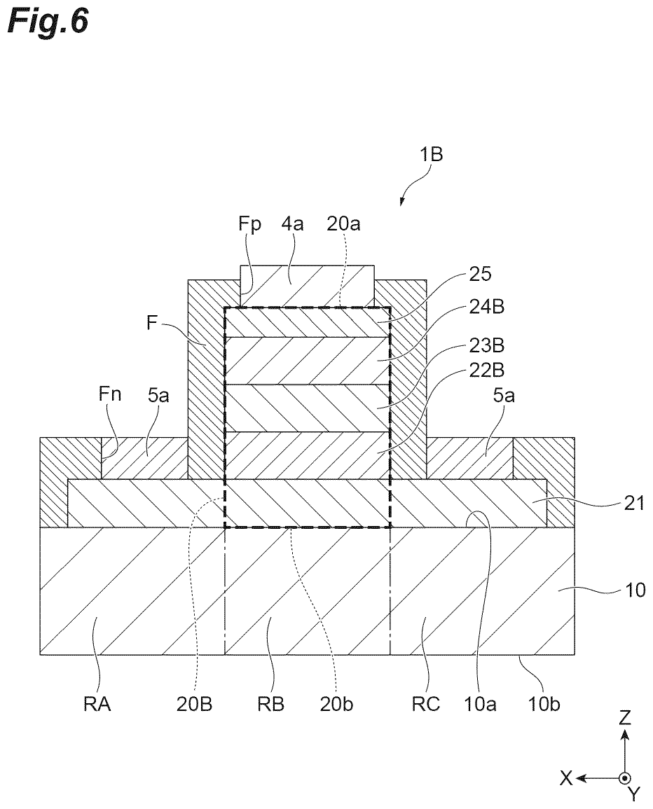

FIG. 6 is a schematic cross-sectional view of a semiconductor light-receiving element according to a third embodiment. As illustrated in FIG. 6, a semiconductor light-receiving element 1B is different from the semiconductor light-receiving element 1 according to the first embodiment in that a semiconductor laminated portion 20B is included instead of the semiconductor laminated portion 20. The semiconductor laminated portion 20B is different from the semiconductor laminated portion 20 in that an electron transit layer 22B is included instead of the capacitance reducing layer 22, a light absorbing layer 23B is included instead of the light absorbing layer 23, and a diffusion blocking layer 24B is included instead of the cap layer 24.

The light absorbing layer 23B includes In Gal-xAs and has the second conductivity type (P-type here, P⁺-type as an example). An In composition x in the light absorbing layer 23B is 0.55 or more (and less than 1). As an example, the In composition x may be 0.57 or more, and is 0.59 or more (for example, 0.59) here. Furthermore, the thickness of the light absorbing layer 23B is 1.8 μm or less. For example, a thickness of the light absorbing layer 23B may be 0.3 μm or less, and may be 0.1 μm or less here. As an example, the thickness of the light absorbing layer 23B may be 0.02 μm or more and 0.5 μm or less. The width of the light absorbing layer 23B along the incident direction of the light L on the side surface 20s (Y-axis direction) is, for example, 2 μm or more and 10 μm or less.

The electron transit layer 22B is provided between the light absorbing layer 23B and the buffer layer 21, and has the first conductivity type (N-type here, N⁻-type as an example). The electron transit layer 22B is made of N⁻-InAs_{0.15}P as an example. The electron transit layer 22B has an impurity concentration lower than the impurity concentration of the buffer layer 21. A thickness of the electron transit layer 22B is, for example, 0.1 μm or more and 3.0 μm or less, and may be 0.3 μm or more and 3.0 μm or less. In addition, the impurity concentration of the electron transit layer 22B is approximately 2.0x 1014 cm⁻³ or more and 3.0×10¹⁶ cm⁻³ or less.

The diffusion blocking layer 24B has the second conductivity type (P-type here, P⁺-type as an example). The diffusion blocking layer 24B contains InAsP or InGaAsP. Here, the diffusion blocking layer 24B contains InAsP. As an example, the diffusion blocking layer 24B is made of P⁺-InAs_{0.15}P. A thickness of the diffusion blocking layer 24B is, for example, 0.05 μm or more and 2.5 μm or less. In this way, the semiconductor laminated portion 20B includes a fourth semiconductor layer of the second conductivity type located on the opposite side from the substrate 10 with respect to the light absorbing layer 23B and bonded to the light absorbing layer 23B. The fourth semiconductor layer includes the diffusion blocking layer 24B and the contact layer 25.

Note that, in semiconductor light-receiving element 1B, similarly to the buffer layer 21 and the capacitance reducing layer 22 of the semiconductor light-receiving element 1, the buffer layer 21 and the electron transit layer 22B are extended outside the semiconductor laminated portion 20B to form the waveguide portion 3. In other words, the semiconductor light-receiving element 1B is of the side incidence type. In semiconductor light-receiving element 1B, the buffer layer 21 and the electron transit layer 22B are optical waveguide layers of the first conductivity type provided between the substrate 10 and the light absorbing layer 23B. In semiconductor light-receiving element 1B, the light L incident from the side surface 20s reaches the light absorbing layer 23B via the optical waveguide layers.

The semiconductor light-receiving element 1B can achieve similar effects to those of the semiconductor light-receiving element 1. In addition, the semiconductor light-receiving element 1B takes into consideration movement of electrons only by using a UTC structure, and is expected to improve responsiveness when the light absorbing layer 23B is thin. Further, since InAsP and InGaAsP are expected to have faster electron mobility than InP, improvement of responsiveness with the same film thickness can be expected.

In addition, in the semiconductor light-receiving element 1B, the semiconductor laminated portion 20B includes the diffusion blocking layer 24B of the second conductivity type which contains InAsP and is provided on the light absorbing layer 23B on the opposite side from the substrate 10 with respect to the light absorbing layer 23B, and the contact layer 25 of the second conductivity type which contains InGaAs and is provided on the diffusion blocking layer 24B on the opposite side from the substrate 10 with respect to the light absorbing layer 23B. Further, the fourth semiconductor layer includes the contact layer 25 and the diffusion blocking layer 24B, and a second part to which the electrode 4 is connected is a front surface of the contact layer 25. For this reason, it is possible to reduce the contact resistance of the electrode 4 and to reduce the series resistance. In this way, it is possible to suppress deterioration of responsiveness. Furthermore, by using a material having a refractive index lower than the refractive index of the light absorbing layer 23B for the diffusion blocking layer 24B, it becomes possible to suitably confine light in the light absorbing layer 23B.

In addition, in the semiconductor light-receiving element 1B, the thickness of the electron transit layer 22B is 0.3 μm or more and 3.0 μm or less, and the impurity concentration of the electron transit layer 22B is 2.0×10¹⁴ cm⁻³ or more and 3.0×10¹⁶ cm⁻³ or less. Therefore, by setting an upper limit of the impurity concentration of the electron transit layer 22B as described above, the electron transit layer 22B can be suitably depleted when a bias is applied. In addition, by setting the thickness of the electron transit layer 22B in the above range, it is possible to suppress a decrease in response speed and an increase in series resistance of the semiconductor light-receiving element 1B.

Note that, in the semiconductor light-receiving element 1B, similarly to the semiconductor light-receiving element 1A, the buffer layer 21 and the diffusion blocking layer 24B terminate at the side surface 20s (end surfaces of the buffer layer 21 and the diffusion blocking layer 24B are flush with an end surface of the light absorbing layer 23B), and the optical waveguide layer 27A can be provided between the buffer layer 21 and the substrate 10. In this case, the semiconductor laminated portion 20B includes the buffer layer 21 (fifth semiconductor layer) of the first conductivity type provided between the optical waveguide layer 27A and the light absorbing layer 23B, and the electron transit layer 22B of the first conductivity type which has an impurity concentration lower than the impurity concentration of the buffer layer 21 and is provided between the buffer layer 21 and the light absorbing layer 23B. In this way, by making the impurity concentration of the electron transit layer 22B relatively low, the electron transit layer 22B is depleted when a bias is applied, so that speed is further increased due to a decrease in capacitance.

Further, in this case, the electron transit layer 22B may have an impurity concentration lower than the impurity concentration of the light absorbing layer 23B, have a band gap larger than the band gap of the light absorbing layer 23B, and be provided between the light absorbing layer 23B and the optical waveguide layer 27A. In this case, the capacitance can be reduced by relatively lowering the impurity concentration of the electron transit layer 22B. Furthermore, by lowering the impurity concentration of the electron transit layer 22B, it is possible to facilitate depletion and reduce a barrier with respect to the light absorbing layer 23B.

In addition, in the semiconductor light-receiving element 1B, the semiconductor laminated portion 20B may include a sixth semiconductor layer which is provided between the light absorbing layer 23B and the diffusion blocking layer 24B and has a band gap between a band gap of the light absorbing layer 23B and a band gap of the diffusion blocking layer 24B. In this case, by providing a layer having a band gap between that of the light absorbing layer 23B and that of the diffusion blocking layer 24B between the layers, a barrier between the respective layers can be reduced, and response degradation can be suppressed.

### Fourth Embodiment

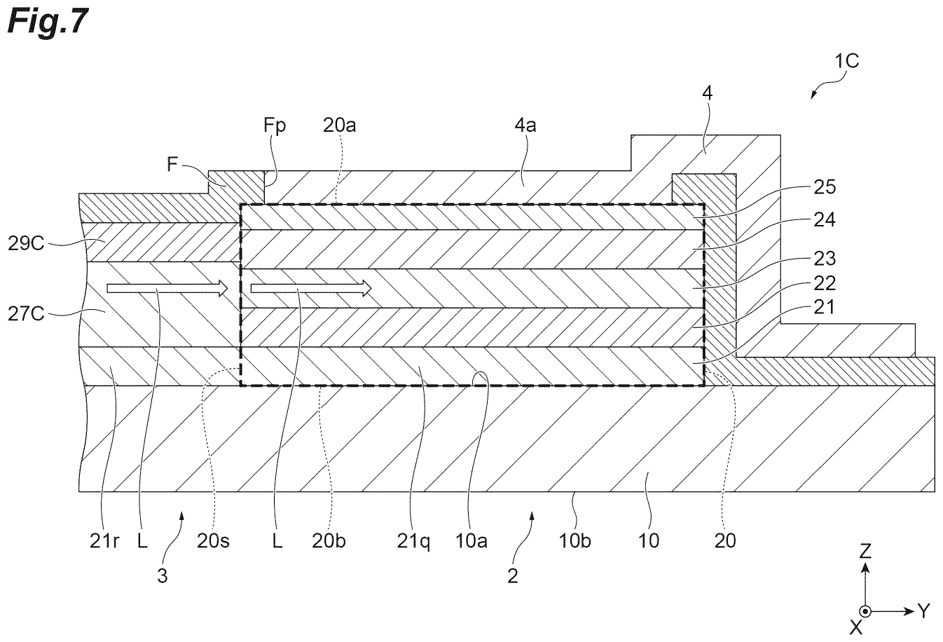

FIG. 7 is a schematic cross-sectional view of a semiconductor light-receiving element according to a fourth embodiment. As illustrated in FIG. 7, a semiconductor light-receiving element 1C is different from the semiconductor light-receiving element 1 according to the first embodiment in that an optical waveguide layer 27C and a cladding layer 29C are further included. In the semiconductor light-receiving element 1C, similarly to the semiconductor light-receiving element 1, the buffer layer 21 includes a part 21q included in the semiconductor laminated portion 20 and a part 21r extending from the side surface 20s of the semiconductor laminated portion 20 to the outside of the semiconductor laminated portion 20, and the capacitance reducing layer 22 terminates at the side surface 20s.

Further, in the semiconductor light-receiving element 1C, in the waveguide portion 3, the optical waveguide layer 27C and the cladding layer 29C are stacked in this order and provided on the part 21r of the buffer layer 21. The optical waveguide layer 27C has a refractive index at least higher than the refractive index of the buffer layer 21 and the refractive index of the cladding layer 29C. For example, the optical waveguide layer 27C contains InGaAsP. The optical waveguide layer 27A may be made of a material not including a dopant (for example, a non-doped material) to reduce optical loss. Alternatively, the optical waveguide layer 27C may be made of an insulating material for a similar reason.

The cladding layer 29C may be made of, for example, InP, InAsP, InGaAsP, etc. The cladding layer 29C has a refractive index lower than at least the refractive index of the optical waveguide layer 27C. A front surface of the cladding layer 29C on the opposite side from the optical waveguide layer 27C is covered with the protective film F. End surfaces of the optical waveguide layer 27C and the cladding layer 29C in an optical waveguide direction (Y-axis direction) are bonded to the side surface 20s of the semiconductor laminated portion 20. In this way, the optical waveguide layer 27C is optically coupled to the semiconductor laminated portion 20.

Here, a thickness of the optical waveguide layer 27C is set to be greater than the sum of the thickness of the capacitance reducing layer 22 and the thickness of the light absorbing layer 23. As a result, the optical waveguide layer 27C reaches the cap layer 24 beyond an interface between the buffer layer 21 and the capacitance reducing layer 22 and an interface between the light absorbing layer 23 and the cap layer 24 in a stacking direction (Z-axis direction) of the semiconductor laminated portion 20. The refractive index of the light absorbing layer 23 can be set to be higher than the refractive indexes of the capacitance reducing layer 22 and the cap layer 24. In this way, the light L propagating through the optical waveguide layer 27C and incident on the semiconductor laminated portion 20 from the side surface 20s transitions to the light absorbing layer 23 and is absorbed in the light absorbing layer 23. In other words, the semiconductor light-receiving element 1C is of the side incidence type.

In particular, in the semiconductor light-receiving element 1C, the optical waveguide layer 27C and the light absorbing layer 23 are directly coupled to each other at the side surface 20s. For this reason, in the semiconductor light-receiving element 1C, the light L propagating through the optical waveguide layer 27C is directly incident on the light absorbing layer 23 in an incident direction (Y-axis direction) with respect to the side surface 20s. Note that the optical waveguide layer 27C and the cladding layer 29C may be formed by, for example, re-growing a semiconductor layer on the buffer layer 21.

The above semiconductor light-receiving element 1C can also achieve similar effects to those of the semiconductor light-receiving element 1, except for the effect of the light L incident from the side surface 20s reaching the light absorbing layer 23 via the optical waveguide layer. In addition, by disposing the optical waveguide layer 27C immediately to the side of the light absorbing layer 23, the effect of light traveling back and forth between the core layer and the cladding layer can be reduced. In this way, it is possible to increase coupling efficiency and to increase sensitivity over a short distance.

Note that, in the semiconductor light-receiving element 1C, the semiconductor laminated portion 20 may be modified to the semiconductor laminated portion 20B similarly to the semiconductor light-receiving element 1B. In this case, the light absorbing layer 23 is modified to the light absorbing layer 23B of the second conductivity type, and the capacitance reducing layer 22 and the cap layer 24 are modified to the electron transit layer 22B and the diffusion blocking layer 24B, respectively. A relationship of the optical waveguide layer 27C and the cladding layer 29C with each layer is similar.

### Fifth Embodiment

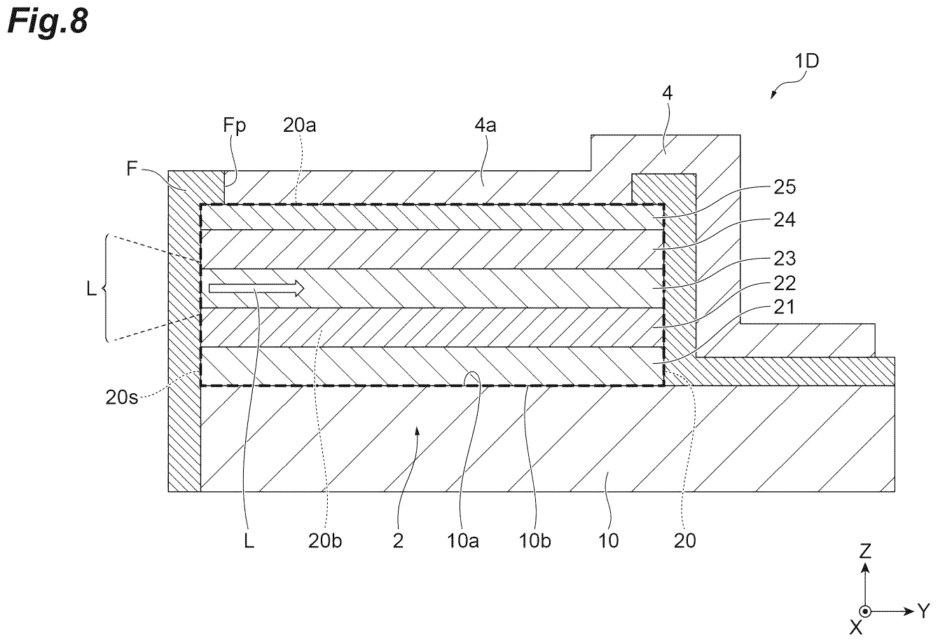

FIG. 8 is a schematic cross-sectional view of a semiconductor light-receiving element according to a fifth embodiment. As illustrated in FIG. 8, a semiconductor light-receiving element 1D is different from the semiconductor light-receiving element 1 according to the first embodiment in that the side surface 20s of the semiconductor laminated portion 20 is covered with the protective film F. Therefore, in the semiconductor light-receiving element 1D, end surfaces of all layers of the semiconductor laminated portion 20 are flush to form the side surface 20s. In this way, in the semiconductor light-receiving element 1D, the end surface of the light absorbing layer 23 is exposed via the protective film F, for example, so that the light L propagating through space, an optical fiber, etc. can be coupled to the end surface of the light absorbing layer 23 at the side surface 20s. Therefore, the semiconductor light-receiving element 1D is of the side incidence type in which incidence of the light L is received from the side surface 20s of the semiconductor laminated portion 20. In particular, in semiconductor light-receiving element 1D, light is directly incident on the light absorbing layer 23 in the incident direction (Y-axis direction) with respect to the side surface 20s.

The above semiconductor light-receiving element 1D can also achieve similar effects to those of the semiconductor light-receiving element 1, except for the effect of the light L incident from the side surface 20s reaching the light absorbing layer 23 via the optical waveguide layer. In addition, by making light directly incident on the light absorbing layer 23, it is unnecessary to create the waveguide portion 3 on a chip, and thus a chip size can be minimized. In addition, since the waveguide layer is not required, and a stacked structure can be considered only by a core layer (light absorbing layer) and a cladding layer (by epitaxial growth, for example), simplification is possible.

Note that, in the semiconductor light-receiving element 1D, the semiconductor laminated portion 20 may be modified to the semiconductor laminated portion 20B similarly to the semiconductor light-receiving element 1B. In this case, the light absorbing layer 23 is modified to the light absorbing layer 23B of the second conductivity type, and the capacitance reducing layer 22 and the cap layer 24 are modified to the electron transit layer 22B and the diffusion blocking layer 24B, respectively.

### Sixth Embodiment

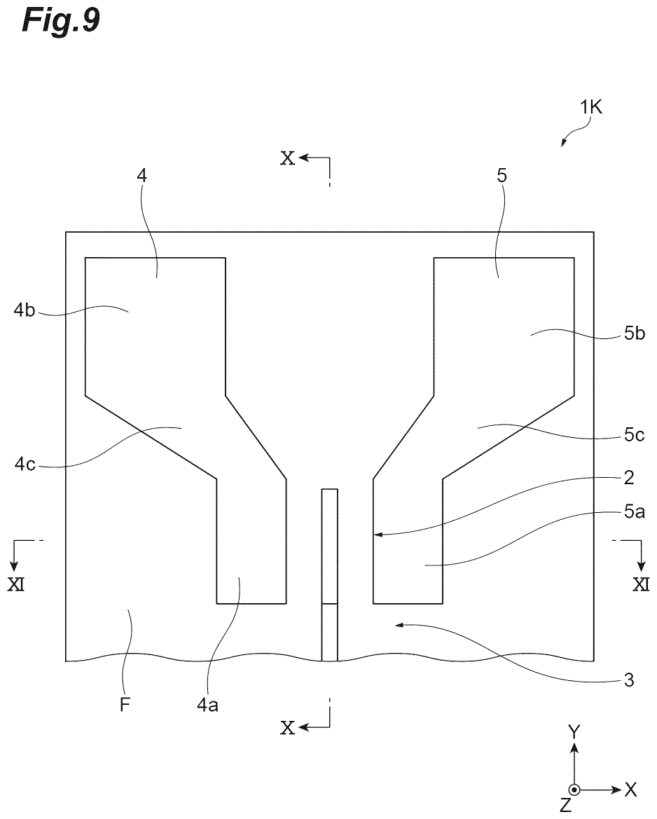

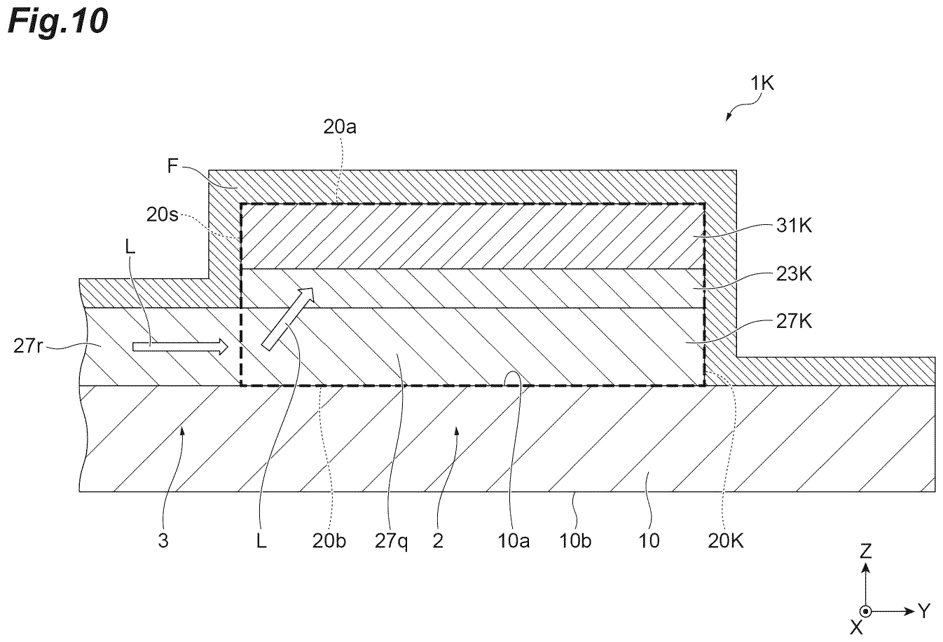

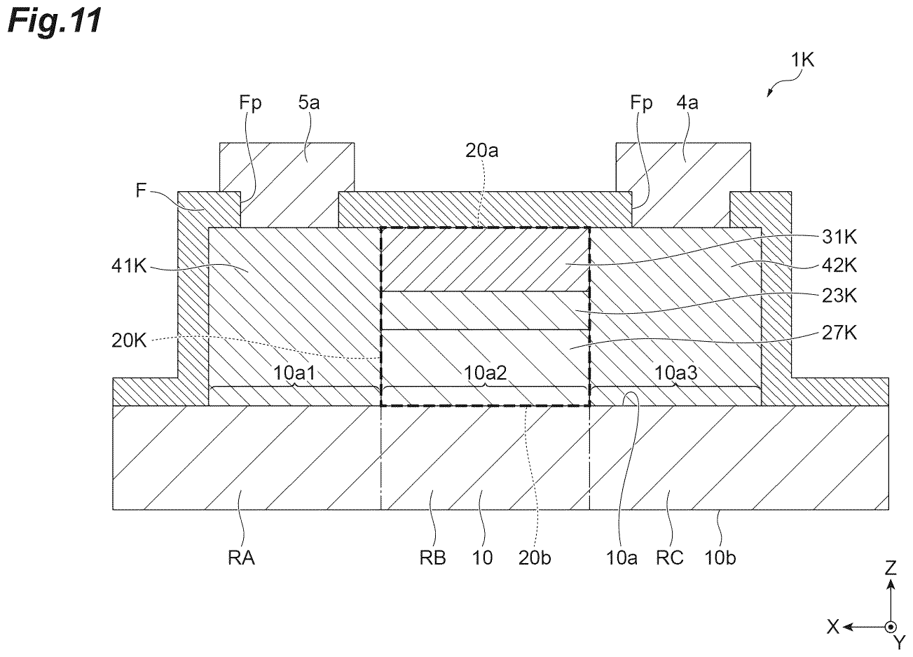

FIG. 9 is a schematic plan view of a semiconductor light-receiving element according to a sixth embodiment. FIG. 10 is a schematic cross-sectional view taken along line X-X of FIG. 9. FIG. 11 is a schematic cross-sectional view taken along line XI-XI of FIG. 9. As illustrated in FIGS. 7 to 9, a semiconductor light-receiving element 1K includes a semiconductor laminated portion 20K provided on the front surface 10a of the substrate 10. The front surface 10a (main surface) of the substrate 10 includes a first region 10a1, a second region 10a2, and a third region 10a3 arranged in order along the X-axis direction (first direction). The semiconductor laminated portion 20K is provided on the second region 10a2.

In addition, the semiconductor light-receiving element 1K includes a first semiconductor portion 41K of the first conductivity type (N-type here, N⁺-type as an example) provided on the first region 10a1, and a second semiconductor portion 42K of the second conductivity type (P-type here, P⁺-type as an example) provided on the third region 10a3. In this way, a light absorbing layer 23K, which will be described later, and the semiconductor laminated portion 20K are disposed between the first semiconductor portion 41K and the second semiconductor portion 42K, and are embedded in the first semiconductor portion 41K and the second semiconductor portion 42K. The first semiconductor portion 41K and the second semiconductor portion 42K are made of, for example, InP, InAsP, InGaAaP, etc.

The protective film F covers the front surface 20a of the semiconductor laminated portion 20K. Meanwhile, the protective film F has an opening Fn to expose a part of a front surface (top surface) of the first semiconductor portion 41K, and an opening Fp to expose a part of a front surface (top surface) of the second semiconductor portion 42K. The electrode 4 (joint portion 4a) is bonded and electrically connected to the second semiconductor portion 42K through the opening Fp, and the electrode 5 (joint portion 5a) is bonded and electrically connected to the first semiconductor portion 41K through the opening Fn. Note that contact layers may be provided between the first semiconductor portion 41K and the second semiconductor portion 42K and the electrodes 4 and 5.

The semiconductor laminated portion 20K includes the light absorbing layer 23K, an optical waveguide layer 27K provided between the light absorbing layer 23K and the substrate 10, and a cladding layer 31K provided on the light absorbing layer 23K on the opposite side from the substrate 10. The light absorbing layer 23K is of I-type or the first conductivity type (for example, N⁻-type). The light absorbing layer 23K includes InGaAs. Here, the light absorbing layer 23K is made of N InₓGa₁₋ₓAs. Further, the In composition x in the light absorbing layer 23K is 0.55 or more (and less than 1). As an example, the In composition x may be 0.57 or more, and is 0.59 or more here (as an example, 0.59). In addition, a thickness of the light absorbing layer 23K is 0.6 μm or more and 1.8 μm or less. As an example, the thickness of the light absorbing layer 23K may be 1.2 μm or less, and is 0.7 μm or less here (as an example, 0.7 μm). A width of the light absorbing layer 23K along the incident direction of the light L on the side surface 20s (the Y-axis direction) is, for example, 2 μm or more and 10 μm or less.

The cladding layer 31K may be made of, for example, InP, InAsP, InGaAsP, etc. The cladding layer 31K has a refractive index lower than the refractive index of the light absorbing layer 23K. Here, the front surface 20a of the semiconductor laminated portion 20K is a front surface of the cladding layer 31K on the opposite side from the light absorbing layer 23K. The optical waveguide layer 27K may include, for example, InGaAsP (is made of InGaAsP). The optical waveguide layer 27K may be made of a material not including a dopant (for example, a non-doped material) to reduce optical loss. Alternatively, the optical waveguide layer 27K may be made of an insulating material for a similar reason.

Similarly to the optical waveguide layer 27A, the optical waveguide layer 27K includes the part 27q included in the semiconductor laminated portion 20K and the part 27r that extends from the side surface 20s of the semiconductor laminated portion 20K to the outside of the semiconductor laminated portion 20K. A front surface of the part 27r on the opposite side from the substrate 10 is covered by the protective film F. In the semiconductor light-receiving element 1K, the waveguide portion 3 is formed by the part 27r. The semiconductor light-receiving element 1K is of the side incidence type in which incidence of the light L guided by the optical waveguide layer 27K in the waveguide portion 3 is received from the side surface 20s of the semiconductor laminated portion 20K.

In the semiconductor light-receiving element 1K, the light L propagating through the waveguide portion 3 (optical waveguide layer 27K) is incident on the semiconductor laminated portion 20K from the side surface 20s of the semiconductor laminated portion 20K, transitions from the optical waveguide layer 27K side to the light absorbing layer 23K, and is absorbed in the light absorbing layer 23K. That is, the light L incident from the side surface 20s reaches the light absorbing layer 23K via the optical waveguide layer 27K. Note that, in the semiconductor light-receiving element 1K, lattice relaxation between the substrate 10 and the light absorbing layer 23K can be achieved in the optical waveguide layer 27K.

The semiconductor light-receiving element 1K can achieve similar effects to those of the semiconductor light-receiving element 1 according to the first embodiment. In addition, by using a material having a higher refractive index than that of the optical waveguide layer 27K and a lower refractive index than that of the light absorbing layer 23K, light can be guided to the absorbing layer more efficiently.

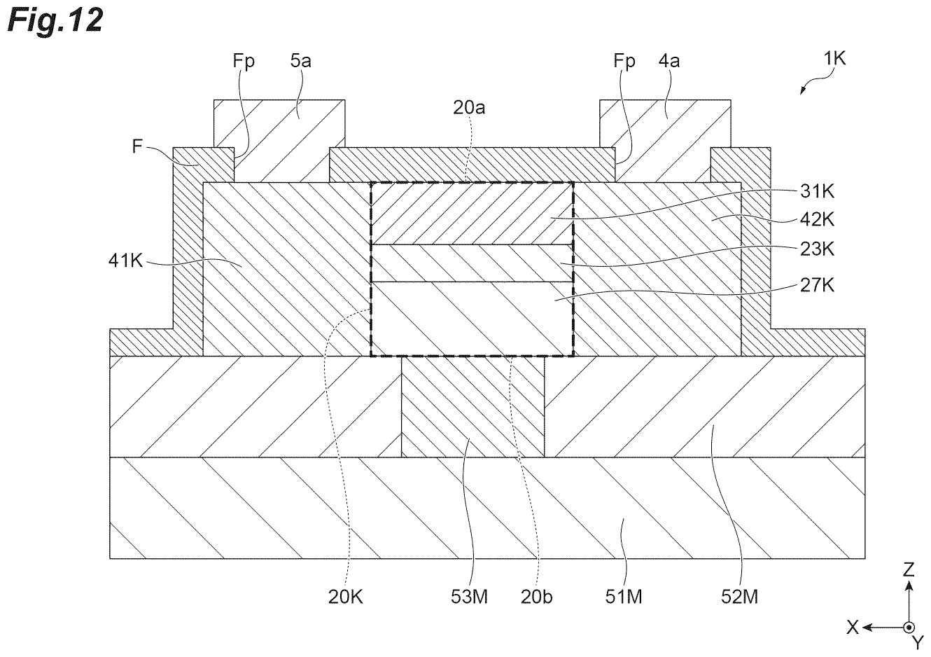

Note that, as illustrated in FIG. 12, in the semiconductor light-receiving element 1K, while the substrate 10 is removed by etching, polishing, etc., the semiconductor laminated portion 20K may be directly bonded to a separately prepared substrate. In an example of FIG. 12, a substrate 10M including a first layer 51M and a second layer 52M stacked together is prepared, and the semiconductor laminated portion 20K is directly bonded to the first layer 51M. In this instance, the optical waveguide layer 27K of the semiconductor laminated portion 20K can be directly bonded to a waveguide 53M formed in the second layer 52M. The first layer 51M and the second layer 52M include, for example, SiO₂, and the waveguide 53M includes, for example, Si. In this way, when the semiconductor light-receiving element 1K is manufactured by separately constructing and bonding the substrate 10M and the semiconductor laminated portion 20K, and a waveguide having a large area can be manufactured at low cost.

### Seventh Embodiment

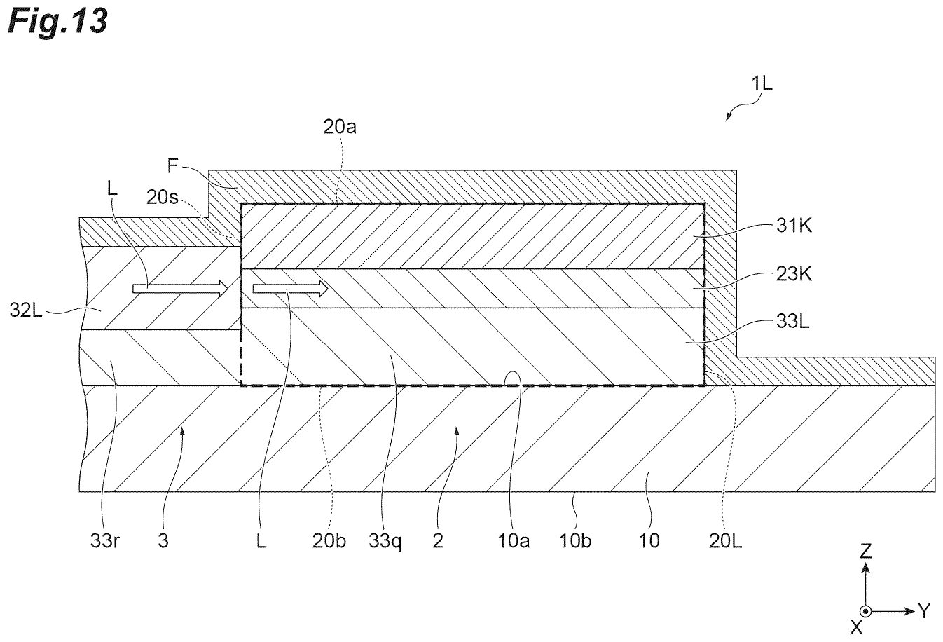

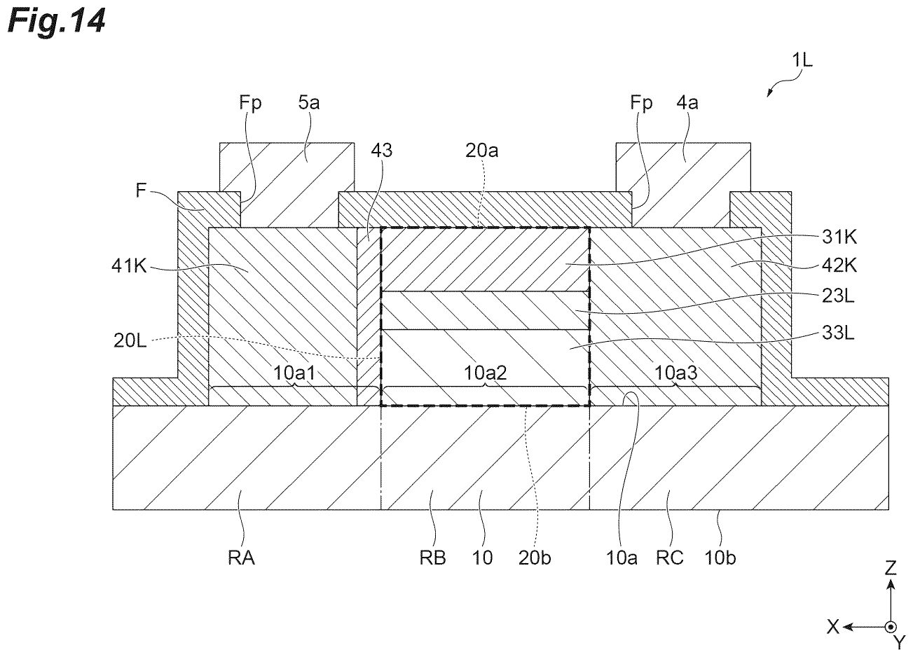

FIGS. 13 and 14 are schematic cross-sectional views of a semiconductor light-receiving element according to a seventh embodiment. FIG. 13 illustrates a cross section corresponding to a cross section taken along line X-X of FIG. 9 of the sixth embodiment, and FIG. 14 illustrates a cross section corresponding to a cross section taken along line XI-XI of FIG. 9 of the sixth embodiment. A semiconductor light-receiving element 1L illustrated in FIGS. 13 and 14 is different from the semiconductor light-receiving element 1K according to the sixth embodiment in that a semiconductor laminated portion 20L is included instead of the semiconductor laminated portion 20K, and an optical waveguide layer 32L is included.

The semiconductor laminated portion 20L is different from the semiconductor laminated portion 20K in that a light absorbing layer 23L is included instead of the light absorbing layer 23K, and in that a cladding layer 33L is included instead of the optical waveguide layer 27K. The cladding layer 33L may be made of the same material as that of the cladding layer 31K. The cladding layer 33L extends beyond the side surface 20s of the semiconductor laminated portion 20L to the outside of the semiconductor laminated portion 20L. That is, the cladding layer 33L includes a part 33q included in the semiconductor laminated portion 20L and a part 33r extending from the side surface 20s of the semiconductor laminated portion 20L to the outside of the semiconductor laminated portion 20L. The optical waveguide layer 32L is stacked on the part 33r of the cladding layer 33L on the outside of the semiconductor laminated portion 20L. A front surface of the optical waveguide layer 32L on the opposite side from the substrate 10 is covered by the protective film F.

The light absorbing layer 23L corresponds to a light absorbing layer obtained by changing the conductivity type of the light absorbing layer 23K to the second conductivity type (for example, P⁻-type). In the semiconductor light-receiving element 1L, an electron transit layer 43 of the first conductivity type (for example, N⁻-type) is provided between the first semiconductor portion 41K of the first conductivity type and the side surface 20s of the semiconductor laminated portion 20L. A material, etc. of the electron transit layer 43 is similar to that of the electron transit layer 22B. In this way, by using the UTC structure, only movement of electrons is taken into consideration, and improved responsiveness is expected when the light absorbing layer 23L is thin. Further, since it is expected that InAsP and InGaAsP have faster electron mobility when compared to InP, improved responsiveness can be expected for the same film thickness.

In the semiconductor light-receiving element 1L, the light L propagating through the optical waveguide layer 32L and incident on the semiconductor laminated portion 20L from the side surface 20s transitions to the light absorbing layer 23L and is absorbed in the light absorbing layer 23L. That is, the semiconductor light-receiving element 1L is of the side incidence type. In particular, in the semiconductor light-receiving element 1L, the optical waveguide layer 32L and the light absorbing layer 23L are directly coupled to each other at the side surface 20s. For this reason, in the semiconductor light-receiving element 1L, the light L propagating through the optical waveguide layer 32L is directly incident on the light absorbing layer 23L in the incident direction (Y-axis direction) with respect to the side surface 20s.

The above semiconductor light-receiving element 1L can also achieve similar effects to those of the semiconductor light-receiving element 1, except for the effect of the light L incident from the side surface 20s reaching the light absorbing layer 23 via the optical waveguide layer. In addition, by disposing the optical waveguide layer 32L immediately to the side of the light absorbing layer 23L, the effect of light traveling back and forth between the core layer and the cladding layer can be reduced. In this way, it is possible to increase coupling efficiency and to increase sensitivity over a short distance.

Note that, in the semiconductor light-receiving element 1L, the light absorbing layer 23L may be used as the light absorbing layer 23K of the first conductivity type similarly to the semiconductor light-receiving element 1K. In this case, the electron transit layer 43 does not have to be provided. Further, in the semiconductor light-receiving element 1K, the conductivity type of the light absorbing layer 23K may be set to second conductivity type (for example, P —-type), and the electron transit layer 43 may be provided.

### Other Modified Examples

The above embodiments describe one aspect of the disclosure. Therefore, the semiconductor light-receiving element according to the disclosure can be obtained by arbitrarily modifying the above-mentioned semiconductor light-receiving elements 1, 1A, 1B, 1C, 1D, 1K, and 1L.

For example, in the semiconductor light-receiving elements 1, 1A, 1B, 1C, and 1D, the buffer layer 21 is not limited to InAsP, but may contain InGaAsP (or may be made of InGaAsP) for the purpose of increasing the band gap and improving transmittance in the 1.3 μm band, the 1.55 μm band, and the 1.6 μm band. Furthermore, each layer of the semiconductor laminated portion 20 may contain other elements such as Al.

Further, in the semiconductor light-receiving elements 1, 1A, 1B, 1C, and 1D, the buffer layer 21 may include a strain relief layer whose lattice constant continuously changes from the substrate 10 toward the light absorbing layers 23 and 23B so as to approach the lattice constant of the light absorbing layer 23. Further, in the semiconductor light-receiving elements 1, 1A, 1C, and 1D, of the cap layer 24 and the contact layer 25 stacked in this order on the light absorbing layer 23, the cap layer 24 may be omitted, and the contact layer 25 may be formed directly on the light absorbing layer 23. Even in this case, the contact resistance of the electrode 4 is reduced.

Further, when attention is focused on increasing speed, in the semiconductor light-receiving elements 1, 1A, 1B, 1C, and 1D, the light absorbing layers 23 and 23B may be applied to a waveguide type semiconductor light-receiving element. In the waveguide type semiconductor light-receiving element, a ridge waveguide is formed on a semi-insulating InP substrate, and a light-receiving portion including the light absorbing layer 23 and 23B is formed in the ridge waveguide. In this way, even in the waveguide type, by adopting the light absorbing layer 23 and 23B having improved absorptance, it is possible to reduce a length of a light receiving surface along an extension direction of the waveguide and reduce the capacitance. Further, even when the thickness is the same, responsiveness is improved by increasing a traveling speed of electrons.

In addition, in the semiconductor light-receiving elements 1, 1A, 1B, 1C, 1D, 1K, and 1L, for example, after removing the substrate 10 by etching or polishing, the semiconductor laminated portions 20, 20A, 20B, and 20K may be bonded to a substrate made of an insulator such as quartz or a material of a semi-insulating semiconductor other than InP (for example, gallium arsenide, etc.). In other words, in the semiconductor light-receiving element 1, the substrate 10 may include an insulator or a semi-insulating semiconductor and be constructed separately from the semiconductor laminated portions 20, 20A, 20B, and 20K, and the semiconductor laminated portions 20, 20A, 20B, and 20K may be bonded (for example, directly) to the substrate 10. In this way, by manufacturing the semiconductor light-receiving element 1 by separately constructing and bonding the substrate 10 and the semiconductor laminated portions 20, 20A, 20B, and 20K, it is possible to increase a diameter and reduce costs by creating optical components using inexpensive materials.

Furthermore, when bonding the substrate 10 and the semiconductor laminated portions 20, 20A, 20B, 20K, and 20L, which are constructed separately from each other, direct bonding or bonding using a resin can be adopted. When a resin is used to bond the substrate 10 and the semiconductor laminated portions 20, 20A, 20B, 20K, and 20L, there is a possibility that light in a target wavelength band will be absorbed depending on the properties of the resin, but this is not possible with direct bonding.

Further, in the semiconductor light-receiving elements 1, 1A, 1B, 1C, 1D, 1K, and 1L, an MIM structure, an electronic device such as a transistor, an optical circuit including a spot size converter, etc. may be further formed on the substrate 10.

### INDUSTRIAL APPLICABILITY

A semiconductor light-receiving element capable of increasing speed is provided.

### REFERENCE SIGNS LIST

1, 1A, 1B, 1C, 1D, 1K, 1L: semiconductor light-receiving element, 20, 20A, 20B, 20K, 20L: semiconductor laminated portion, 21: buffer layer (strain relief layer, second semiconductor layer, fifth semiconductor layer), 22: capacitance reducing layer, 22B: electron transit layer, 23, 23B, 23K, 23L: light absorbing layer, 24: cap layer (first semiconductor layer), 24B: diffusion blocking layer (fourth semiconductor layer), 25: contact layer (first semiconductor layer, fourth semiconductor layer), 27A, 27C: optical waveguide layer, 4: electrode (second electrode), 5: electrode (first electrode).

1. A semiconductor light-receiving element for receiving incidence of light in a wavelength band of at least one of a 1.3 μm band, a 1.55 μm band, and a 1.6 μm band and generating an electrical signal in response to incident light, the semiconductor light-receiving element comprising:
a substrate;
a semiconductor laminated portion formed on the substrate and including a back surface on the substrate side, a front surface on an opposite side from the substrate, and a side surface extending from the back surface toward the front surface; and
a first electrode and a second electrode electrically connected to the semiconductor laminated portion, wherein:
the semiconductor laminated portion includes
a light absorbing layer of a first conductivity type containing InₓGa₁₋ₓAs,
a buffer layer of the first conductivity type provided between the substrate and the light absorbing layer, and
a first semiconductor layer of a second conductivity type different from the first conductivity type located on an opposite side from the substrate with respect to the light absorbing layer and bonded to the light absorbing layer,
the first electrode is connected to a first part of the first conductivity type of the semiconductor laminated portion located on the substrate side with respect to the light absorbing layer,
the second electrode is connected to a second part of the second conductivity type of the semiconductor laminated portion located on the opposite side from the substrate with respect to the light absorbing layer,
an In composition x in the light absorbing layer is 0.55 or more,
a thickness of the light absorbing layer is 1.8 μm or less,
the semiconductor light-receiving element is of a side incidence type in which incidence of the light is received from the side surface, and
a width of the light absorbing layer along an incident direction of the light with respect to the side surface is 10 μm or less.

2. The semiconductor light-receiving element according to claim 1, wherein the buffer layer includes a strain relief layer having a lattice constant between a lattice constant of the substrate and a lattice constant of the light absorbing layer.

3. The semiconductor light-receiving element according to claim 1, wherein:
the semiconductor laminated portion includes
a cap layer of the second conductivity type provided on the light absorbing layer on the opposite side from the substrate with respect to the light absorbing layer and containing InAsP or InGaAsP, and
a contact layer of the second conductivity type provided on the cap layer on the opposite side from the substrate with respect to the light absorbing layer and containing InGaAs,
the first semiconductor layer includes the contact layer and the cap layer, and
the second part to which the second electrode is connected is a front surface of the contact layer.

4. The semiconductor light-receiving element according to claim 1, wherein the semiconductor laminated portion includes
a second semiconductor layer of the first conductivity type disposed between the substrate and the light absorbing layer, and
a capacitance reducing layer of the first conductivity type having an impurity concentration lower than an impurity concentration of the second semiconductor layer and disposed between the second semiconductor layer and the light absorbing layer.

5. The semiconductor light-receiving element according to claim 3, wherein the semiconductor laminated portion includes a third semiconductor layer provided between the light absorbing layer and the cap layer and having a band gap between a band gap of the light absorbing layer and a band gap of the cap layer.

6. The semiconductor light-receiving element according to claim 1, wherein at least one layer of the buffer layer is semi-insulated by being doped with Fe.

7. The semiconductor light-receiving element according to claim 4, wherein the capacitance reducing layer has an impurity concentration higher than an impurity concentration of the light absorbing layer, has a band gap larger than a band gap of the light absorbing layer, and is provided between the light absorbing layer and the buffer layer.

8. The semiconductor light-receiving element according to claim 7, wherein:
a thickness of the capacitance reducing layer is 0.3 μm or more and 3.0 μm or less, and
an impurity concentration of the capacitance reducing layer is 2.0×10¹⁴ cm⁻³ or more and 3.0×10¹⁶ cm⁻³ or less.

9. The semiconductor light-receiving element according to claim 1, wherein:
an In composition x in the light absorbing layer is 0.57 or more, and
a thickness of the light absorbing layer is 1.2 μm or less.

10. The semiconductor light-receiving element according to claim 9, wherein:
the In composition x in the light absorbing layer is 0.59 or more, and
the thickness of the light absorbing layer is 0.7 μm or less.

11. The semiconductor light-receiving element according to claim 1, wherein:
the substrate includes an insulator or a semi-insulating semiconductor, and
the semiconductor laminated portion is bonded to the substrate.

12. A semiconductor light-receiving element for receiving incidence of light in a wavelength band of at least one of a 1.3 μm band, a 1.55 μm band, and a 1.6 μm band and generating an electrical signal in response to incident light, the semiconductor light-receiving element comprising:
a substrate;
a semiconductor laminated portion formed on the substrate and including a back surface on the substrate side, a front surface on an opposite side from the substrate, and a side surface extending from the back surface toward the front surface; and
a first electrode and a second electrode electrically connected to the semiconductor laminated portion, wherein:
the semiconductor laminated portion includes
a light absorbing layer of a second conductivity type containing InₓGa₁₋ₓAs,
a buffer layer of a first conductivity type different from the second conductivity type provided between the substrate and the light absorbing layer, and
a fourth semiconductor layer of the second conductivity type located on an opposite side from the substrate with respect to the light absorbing layer and bonded to the light absorbing layer,
the first electrode is connected to a first part of the first conductivity type of the semiconductor laminated portion located on the substrate side with respect to the light absorbing layer,
the second electrode is connected to a second part of the second conductivity type of the semiconductor laminated portion located on the opposite side from the substrate with respect to the light absorbing layer,
an In composition x in the light absorbing layer is 0.55 or more,
a thickness of the light absorbing layer is 1.8 μm or less,
the semiconductor light-receiving element is of a side incidence type in which incidence of the light is received from the side surface, and
a width of the light absorbing layer along an incident direction of the light with respect to the side surface is 10 μm or less.

13. The semiconductor light-receiving element according to claim 12, wherein the buffer layer includes a strain relief layer having a lattice constant between a lattice constant of the substrate and a lattice constant of the light absorbing layer.

14. The semiconductor light-receiving element according to claim 12, wherein:
the semiconductor laminated portion includes
a diffusion blocking layer of the second conductivity type provided on the light absorbing layer on the opposite side from the substrate with respect to the light absorbing layer and containing InAsP or InGaAsP, and
a contact layer of the second conductivity type provided on the diffusion blocking layer on the opposite side from the substrate with respect to the light absorbing layer and containing InGaAs,
the fourth semiconductor layer includes the contact layer and the diffusion blocking layer, and
the second part to which the second electrode is connected is a front surface of the contact layer.

15. The semiconductor light-receiving element according to claim 12, wherein:
the semiconductor laminated portion includes an electron transit layer of the first conductivity type provided between the buffer layer and the light absorbing layer, and
an impurity concentration of the electron transit layer is lower than an impurity concentration of the buffer layer.

16. The semiconductor light-receiving element according to claim 14, wherein the semiconductor laminated portion includes a sixth semiconductor layer provided between the light absorbing layer and the diffusion blocking layer having a band gap between a band gap of the light absorbing layer and a band gap of the diffusion blocking layer.

17. The semiconductor light-receiving element according to claim 12, wherein at least one layer of the buffer layer is semi-insulated by being doped with Fe.

18. The semiconductor light-receiving element according to claim 15, wherein the electron transit layer has an impurity concentration lower than an impurity concentration of the light absorbing layer, has a band gap larger than a band gap of the light absorbing layer, and is provided between the light absorbing layer and the buffer layer.

19. The semiconductor light-receiving element according to claim 18, wherein:
a thickness of the electron transit layer is 0.3 μm or more and 3.0 μm or less, and
the impurity concentration of the electron transit layer is 2.0×10¹⁴ cm⁻³ or more and 3.0×10¹⁶ cm⁻³ or less.

20. The semiconductor light-receiving element according to claim 12, wherein:
the In composition x in the light absorbing layer is 0.57 or more, and
the thickness of the light absorbing layer is 0.3 μm or less.

21. The semiconductor light-receiving element according to claim 12, wherein:
the In composition x in the light absorbing layer is 0.59 or more, and
the thickness of the light absorbing layer is 0.1 μm or less.

22. The semiconductor light-receiving element according to claim 12, wherein:
the substrate includes an insulator or a semi-insulating semiconductor, and
the semiconductor laminated portion is bonded to the substrate.

23. A semiconductor light-receiving element for receiving incidence of light in a wavelength band of at least one of a 1.3 μm band, a 1.55 μm band, and a 1.6 μm band and generating an electrical signal in response to incident light, the semiconductor light-receiving element comprising:
a substrate having a main surface including a first region, a second region, and a third region arranged in order along a first direction;
a semiconductor laminated portion formed on the second region and including a back surface on the substrate side, a front surface on an opposite side from the substrate, and a side surface extending from the back surface toward the front surface;
a first semiconductor portion of a first conductivity type formed on the first region;
a second semiconductor portion of a second conductivity type different from the first conductivity type formed on the third region;
a first electrode electrically connected to the first semiconductor portion;
a second electrode electrically connected to the second semiconductor portion; and
an optical waveguide formed on the second region, extending along the main surface and along a second direction intersecting the first direction toward the side surface, and coupled to the side surface, wherein:
the semiconductor laminated portion includes a light absorbing layer containing InₓGa₁₋ₓAs,
an In composition x in the light absorbing layer is 0.55 or more,
a thickness of the light absorbing layer is 1.8 μm or less,
the semiconductor light-receiving element is of a side incidence type in which incidence of the light is received from the side surface via the optical waveguide, and
a width of the light absorbing layer along an incident direction of the light with respect to the side surface is 10 μm or less.
